(19) United States
(12) Patent Application Publication
(10) Pub. No.: US 2026/0239619 A1
(43) Pub. Date: Aug. 13, 2026

(54) ELECTRONIC DEVICE HAVING STACKED STRUCTURES

(71) Applicant: SK hynix Inc., Gyeonggi-do (KR)

(72) Inventors: Ki Hong LEE, Gyeonggi-do (KR); Ji Yeon BAEK, Gyeonggi-do (KR); Seung Ho PYI, Gyeonggi-do (KR)

(21) Appl. No.: 19/538,971

(22) Filed: Feb. 12, 2026

Related U.S. Application Data
(63) Continuation-in-part of application No. 18/764,371, filed on Jul. 5, 2024, now Pat. No. 12,598,754.
Application No. 18/764,371 is a continuation of application No. 18/318,739, filed on May 17, 2023, now Pat. No. 12,048,161.
Application No. 18/318,739 is a continuation of application No. 17/151,412, filed on Jan. 18, 2021, now Pat. No. 11,678,487.
Application No. 17/151,412 is a continuation of application No. 16/298,923, filed on Mar. 11, 2019, now Pat. No. 10,923,497.
Application No. 16/298,923 is a continuation of application No. 15/821,388, filed on Nov. 22, 2017, now Pat. No. 10,269,827.
Application No. 15/821,388 is a continuation of application No. 15/398,467, filed on Jan. 4, 2017, now Pat. No. 9,991,279.
Application No. 15/398,467 is a division of application No. 14/732,390, filed on Jun. 5, 2015, now Pat. No. 9,570,462.

(30) Foreign Application Priority Data
Dec. 29, 2014 (KR) 10-2014-0192025

(51) Int. Cl. H10B 43/27; H10B 43/10; H10B 43/35; H10W 20/00

(52) U.S. Cl. CPC H10B 43/27; H10B 43/10; H10B 43/35; H10W 20/023

(57) ABSTRACT

An electronic device comprises: a first conductive layer; a second conductive layer connected to the first conductive layer; a stacked structure including conductive layers and insulating layers which are alternately stacked, wherein the conductive layers include a selection gate of a selection transistor and gate electrodes of memory cells; a channel layer extending through the stacked structure and including a contact surface connected to the second conductive layer; a memory layer between the channel layer and the stacked structure, wherein the memory layer is not interposed between the contact surface and the second conductive layer; and a sub-insulating layer passing through the selection gate.

### CROSS-REFERENCE TO RELATED APPLICATION

This application is a continuation-in-part of U.S. patent application Ser. No. 18/764,371 filed on Jul. 5, 2024, which is a continuation of U.S. patent application Ser. No. 18/318,739 filed on May 17, 2023, and now U.S. Pat. No. 12,048,161 issued on Jul. 23, 2024, which is a continuation of U.S. patent application Ser. No. 17/151,412 filed on Jan. 18, 2021, and now U.S. Pat. No. 11,678,487 issued on Jun. 13, 2023, which is a continuation of U.S. patent application Ser. No. 16/298,923 filed on Mar. 11, 2019, and now U.S. Pat. No. 10,923,497 issued on Feb. 16, 2021, which is a continuation of U.S. patent application Ser. No. 15/821,388 filed on Nov. 22, 2017, and now U.S. Pat. No. 10,269,827 issued on Apr. 23, 2019, which is a continuation of U.S. patent application Ser. No. 15/398,467 filed on Jan. 4, 2017, and now U.S. Pat. No. 9,991,279 issued on Jun. 5, 2018, which is a division of U.S. patent application Ser. No. 14/732,390 filed on Jun. 5, 2015, and now U.S. Pat. No. 9,570,462 issued on Feb. 14, 2017, which claims priority to Korean patent application number 10-2014-0192025, filed on Dec. 29, 2014. The disclosure of each of the foregoing applications is incorporated herein by reference in its entirety.

### BACKGROUND

### Field of Invention

Various exemplary embodiments relate generally to an electronic device and a method for manufacturing the same, and more particularly, to an electronic device including a data storage unit having a three-dimensional structure and a method for manufacturing the same.

### Description of Related Art

All types of electronic devices include data storage units although these data storage units may have different functions and configurations. Performance improvement of electronic devices is continuously evolving. Accordingly, data storage units having a high performance and high capacity in addition to performance improvement are in demand. To achieve such requirements, proposals for electronic devices including high performance, high-capacity data storage units have been made.

The number of electronic devices requiring data storage units which retain data even though power is turned off, is increasing. Recently, data storage units having high storage capacity and high read and write speeds, in addition to retaining data, have been required. Therefore, technical development is being actively conducted to meet these requirements.

### SUMMARY

An embodiment is directed to an electronic device having improved characteristics and that is easy to manufacture, and a manufacturing method thereof.

An electronic device comprises: a first conductive layer; a second conductive layer connected to the first conductive layer; a stacked structure including conductive layers and insulating layers which are alternately stacked, wherein the conductive layers include a selection gate of a selection transistor and gate electrodes of memory cells; a channel layer extending through the stacked structure and including a contact surface connected to the second conductive layer; a memory layer between the channel layer and the stacked structure, wherein the memory layer is not interposed between the contact surface and the second conductive layer; and a sub-insulating layer passing through the selection gate.

An electronic device comprises: a pair of slit insulating layers; a stacked structure disposed between the pair of slit insulating layers and including conductive layers and insulating layers which are alternately stacked, wherein the conductive layers include a selection gate of a selection transistor and gate electrodes of memory cells; a first conductive layer disposed under the stacked structure; a second conductive layer connected to the first conductive layer; a channel layer extending through the stacked structure and including a contact surface connected to the second conductive layer; a memory layer between the channel layer and the stacked structure, wherein the memory layer is not interposed between the contact surface and the second conductive layer; and sub-insulating layers disposed between the pair of slit insulating layers and passing through the selection gate.

### BRIEF DESCRIPTION OF THE DRAWINGS

FIGS. 1A and 1B are cross-sectional views illustrating the structure of an electronic device according to an embodiment, and FIG. 1C is an enlarged view of a region G shown in FIGS. 1A and 1B;

FIGS. 2A to 8A, FIGS. 2B to 8B, and FIGS. 3C and 6C are views illustrating a method of manufacturing an electronic device according to an embodiment;

FIGS. 9A and 9B are cross-sectional views illustrating a method of manufacturing an electronic device according to a modified embodiment;

FIGS. 10A to 10C are cross-sectional views illustrating a method of manufacturing an electronic device according to a modified embodiment;

FIGS. 11A to 11D are layout views illustrating the structure of an electronic device according to a modified embodiment;

FIGS. 12A to 16A and FIGS. 12B to 16B are enlarged views illustrating a method of manufacturing an electronic device according to an embodiment;

FIGS. 17A to 17C and FIGS. 18A to 18C are enlarged views illustrating a method of manufacturing an electronic device according to an embodiment;

FIGS. 19 and 20 are block diagrams illustrating the configuration of a memory system according to an embodiment; and

FIGS. 21 and 22 are block diagrams illustrating the configuration of a computing system according to an embodiment.

FIG. 23 is a diagram illustrating the structure of a semiconductor device in accordance with an embodiment.

FIG. 24 is a diagram illustrating the structure of a semiconductor device in accordance with an embodiment.

FIG. 25 is a diagram illustrating the structure of a semiconductor device in accordance with an embodiment.

FIG. 26A is a diagram illustrating the structure of a semiconductor device in accordance with an embodiment.

FIG. 26B is a diagram illustrating the structure of a semiconductor device in accordance with an embodiment.

FIG. 26C is a diagram illustrating the structure of a semiconductor device in accordance with an embodiment.

FIG. 27A is a diagram illustrating the structure of a semiconductor device in accordance with an embodiment.

FIG. 27B is a diagram illustrating the structure of a semiconductor device in accordance with an embodiment.

FIG. 27C is a diagram illustrating the structure of a semiconductor device in accordance with an embodiment.

FIG. 27D is a diagram illustrating the structure of a semiconductor device in accordance with an embodiment.

FIGS. 28A and 28B are diagrams illustrating the structure of a semiconductor device in accordance with an embodiment.

FIGS. 29A to 29D are a diagram illustrating the structure of a semiconductor device in accordance with an embodiment.

FIGS. 30A and 30B are diagrams illustrating the structure of a semiconductor device in accordance with an embodiment.

FIGS. 31A and 31B are diagrams illustrating the structure of a semiconductor device in accordance with an embodiment.

### DETAILED DESCRIPTION

Hereinafter, various exemplary embodiments will be described in detail with reference to the accompanying drawings.

The drawings are not necessarily illustrated at the specific ratio, and in some exemplary embodiments, in order to clearly show the features of the embodiments, at least some of the structures shown in the drawings may be exaggerated. When a multilayer structure including at least two layers is disclosed in the drawings or the detailed description of the invention, the relative positional relationship between the layers, or arrangement thereof merely reflect the specific embodiment. Thus, the present invention is not limited thereto, and such relative positional relationship and the arrangement may vary. In addition, the drawings or the detailed description of the multilayer structure may not reflect every layer existing in the specific multilayer structure, for example, at least one additional layer may exist between the illustrated two layers. For example, when a first layer is formed on a second layer or on a substrate in the multilayer structure shown in the drawings or the detailed description, the first layer may be directly formed on the second layer or directly formed on the substrate, and at least one layer may also exist between the first layer and the second layer or between the first layer and the substrate.

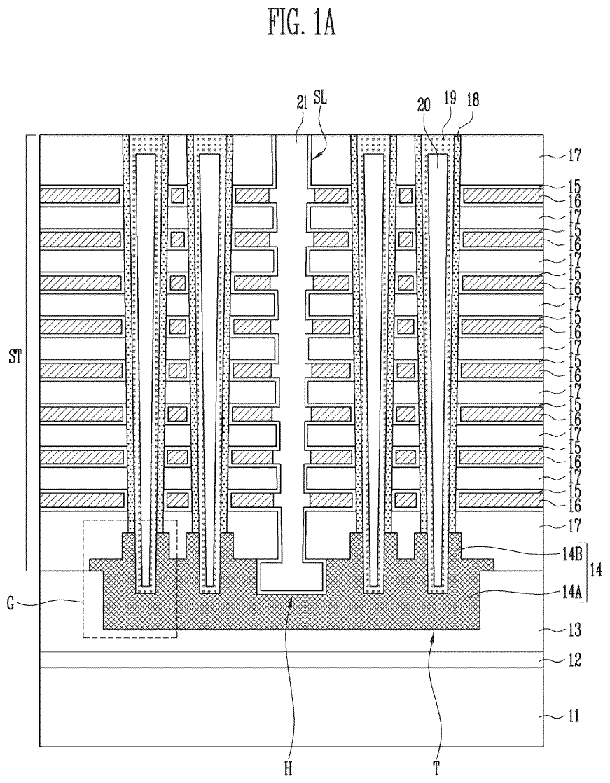

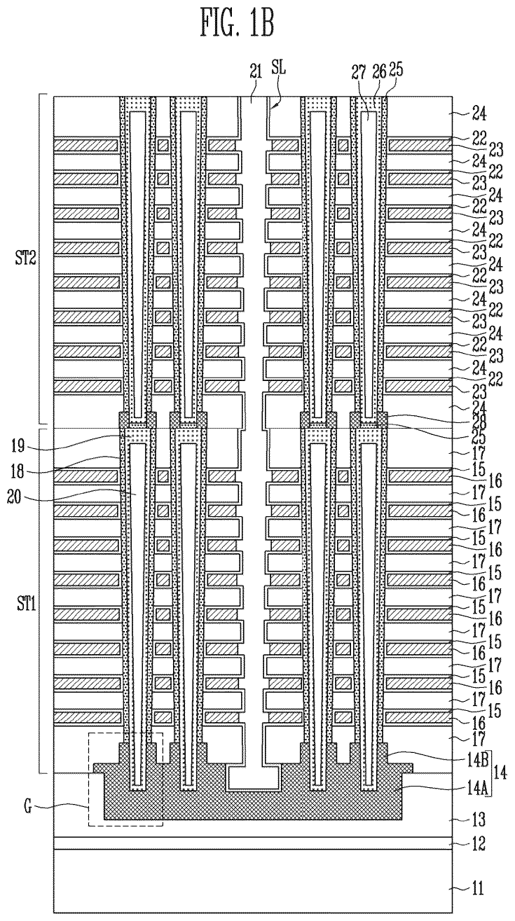

FIGS. 1A and 1B are cross-sectional views illustrating the structure of an electronic device according to an embodiment. The electronic device may be a semiconductor device, and the semiconductor device may include a volatile memory device or a non-volatile memory device.

Referring to FIG. 1A, an electronic device according to an embodiment may include a first source layer 13, a second source layer 14, a structure ST and pillars 19.

The first source layer 13 may be a separate layer configured as source, or be formed by doping a substrate 11 with impurities. According to an embodiment, the first source layer 13 may include a conductive layer including, for example, doped polysilicon. In this embodiment, the electronic device may further include the substrate 11 located under the first source layer 13 and an insulating layer 12 insulating the substrate 11 from the first source layer 13. However, when the first source layer 13 is formed by doping the substrate 11 with impurities, the second source layer 14 may be formed in the substrate 11 and directly contact the substrate 11.

The second source layer 14 may be a conductive layer including, for example, doped silicon and formed in a trench T in the first source layer 13. The second source layer 14 may include a base portion 14A formed in the trench T and protruding portions 14B protruding from the base portion 14A. The base portion 14A may electrically connect neighboring pillars 19. Each of the protruding portions 14B may surround a portion of the pillar 19 and extend into the structure ST. For example, each of the protruding portions 14B may surround a lower portion of the pillar 19. In addition, the second source layer 14 may include a groove H formed in a top surface thereof.

The structure ST may have a stacked body including a plurality of layers stacked on top of each other. The structure ST may include conductive layers 16 and insulating layers 17 stacked alternately with each other. The insulating layer 17 may form the lowest portion of the structure ST which contacts the first conductive layer 13. The lowest insulating layer 17 may be thick enough to insulate the second source layer 14 from the conductive layer 16, and have a greater thickness than the other insulating layers 17. For example, the thickness of the lowest insulating layer 17 may be determined in consideration of the height of the protruding portion 14B of the second source layer 14.

The conductive layers 16 may be gate electrodes of memory cells or selection transistors. For example, at least one lowermost conductive layer 16 may be a lower selection gate of a lower selection transistor, at least one uppermost conductive layer 16 may be an upper selection gate electrode of an upper selection transistor, and the other conductive layers 16 may be gate electrodes of memory cells. The conductive layers 16 may include, for example but are not limited to, silicon, tungsten, tungsten nitride, titanium, titanium nitride, tantalum, tantalum nitride, or the like. In addition, the insulating layers 17 may be insulators for insulating the stacked gate electrodes from each other. For example, the insulating layers 17 may include an oxide, a nitride, or the like. The structure ST may further include dielectric layers 15 surrounding the conductive layers 16. The dielectric layers 15 may be charge blocking layers.

The pillars 19 may pass through the structure ST and extend into the base portion 14A of the second source layer 14. The pillars 19 may include semiconductor layers and be channel layers forming a memory string.

The pillars 19 may be electrically connected to the second source layer 14 and share the second source layer 14. Each of the pillars 19 may include a central portion that may be completely filled, an open central portion, or a combination thereof. The open central portion of each pillar 19 may be filled with a gap-filling insulating layer 20.

Dielectric layers 18 may be interposed between the pillars 19 and the conductive layers 16. Each of the dielectric layers 18 may surround a sidewall of the pillar 19 and be interposed between the pillar 19 and the structure ST. The dielectric layer 18 may have a stacked structure including dielectric layers having different etch selectivities. For example, the dielectric layer 18 may include a first oxide layer, a nitride layer and a second oxide layer stacked in a sequential manner. When the dielectric layer 18 is a memory layer, the dielectric layer 18 may include at least one of a tunnel insulating layer, a data storage layer and a charge blocking layer. The data storage layer may include, for example but is not limited to, silicon, nitride, nanodots, phase-change materials, or the like.

A slit SL may be located between the pillars 19. The slit SL may pass through the structure ST and extend to the second source layer 14. The slit SL may be formed to expose the groove H of the second source layer 14. The slit SL may be filled with a slit insulating layer 21. For example, the slit insulating layer 21 may include an oxide. In addition, the dielectric layers 15 surrounding the conductive layers 16 may be formed along inner surfaces of the slit SL and the groove H.

In referring to FIG. 1B, a first structure ST1 and a lower structure formed under the first structure ST1 may be configured as described above with reference to FIG. 1A. In addition, a second structure ST2 may be formed on the first structure ST1.

The second structure ST2 may include conductive layers 23 and insulating layers 24 stacked alternately with each other. Second channel layers 26 may pass through the second structure ST2 and be coupled to first channel layers 19, respectively. Second memory layers 25 may be interposed between the second channel layers 26 and the second structure ST2. Coupling patterns 28 may be formed at lower sidewalls of the second channel layers 26 not surrounded by the second memory layer 25. The coupling patterns 28 may directly contact lower portions of the second channel layers 26 and upper portions of the first channel layers 19 and couple the first and second channel layers 19 and 26 to each other. In addition, the coupling patterns 28 may be formed in the insulating layer 24.

The slit SL may pass through the first and second structures ST1 and ST2, and the slit insulating layer 21 may be formed through the first and second structures ST1 and ST2.

In the first and second structures ST1 and ST2 having the above-described structure, at least one lower selection transistor, a plurality of memory cells, and at least one upper selection transistor may be coupled in series to form a single string. A plurality of strings may be arranged in a vertical direction. In addition, the plurality of strings may share the first and second source layers 13 and 14.

FIG. 1C is an enlarged view of a region G shown in FIGS. 1A and 1B. Referring to FIG. 1C, the structure ST may include a first opening OP1. The first opening OP1 may be a through hole passing through the structure ST. The pillar 19 may include a through portion 19A formed in the through hole and a protruding portion 19B coupled to the through portion 19A and inserted or extending into the first conductive layer 13.

The base portion 14A of the second source layer 14 may be formed in the first source layer 13 to surround the protruding portion 19B of the pillar 19. In addition, the protruding portion 14B of the second source layer 14 may protrude from the base portion 14A and be formed in the structure ST. The protruding portion 14B may partially surround a portion of the through portion 19A adjacent to the protruding portion 19B of the pillar 19.

In addition, the dielectric layer 18 may be formed on a sidewall of the through portion 19A of the pillar 19 not surrounded by the second source layer 14. That is, the dielectric layer 18 may be interposed between the pillar 19 not surrounded by the second source layer 14 and the structure ST.

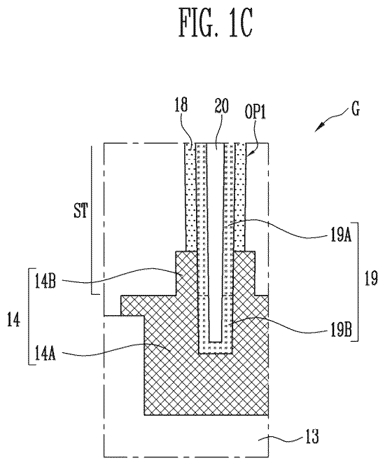

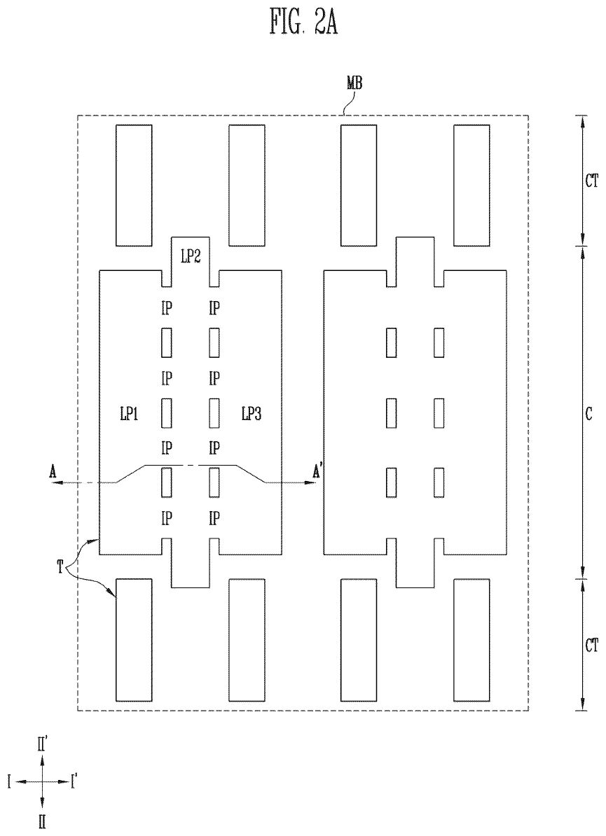

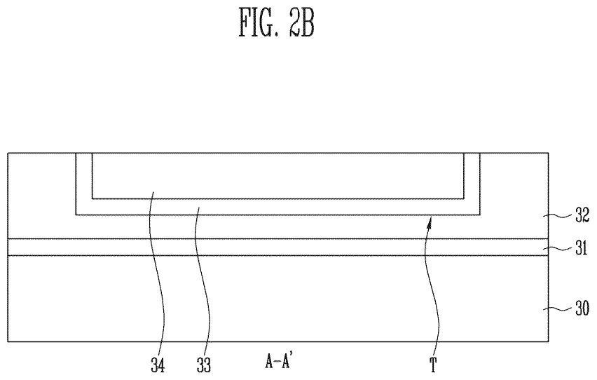

FIGS. 2A to 8A, FIGS. 2B to 8B, and FIGS. 3C and 6C are views illustrating a method of manufacturing an electronic device according to an embodiment. More specifically, FIGS. 2A to 8A are layout views, FIGS. 2B to 8B are cross-sectional views taken along the line A-A′ of FIGS. 2A to 8A, respectively, and FIGS. 3C and 6C are cross-sectional views taken along the line B-B′ of FIGS. 3A and 6A, respectively.

Referring to FIGS. 2A and 2B, a first insulating layer 31 and a first conductive layer 32 may be sequentially formed on a substrate 30. The first conductive layer 32 may be a first source layer and include doped polysilicon. The first insulating layer 31 may insulate the substrate 30 from the first conductive layer 32.

Subsequently, the trench T may be formed in the first conductive layer 32. The trench T may be located in either or both of a cell region C and a contact region CT. The trench T located in the cell region C may include first, second and third line patterns LP1, LP2 and LP3 extending in a second direction II-II′, for example, in a first horizontal direction, and island patterns IP coupling the first to third line patterns LP1 to LP3. Each of the island patterns IP couples two or more of the first, second and third line patterns to each other and extends in a first direction I-I′, for example, in a second horizontal direction across the first horizontal direction. The first to third line patterns LP1 to LP3 may have the same or different lengths, and the same or different widths. According to an embodiment, during subsequent processes, pillars may be formed on the first and third line patterns LP1 and LP3, and a slit may be formed on the second line pattern LP2. Therefore, each of the first and third line patterns LP1 and LP3 may have a greater width than the second line pattern LP2, and the second line pattern LP2 may have a greater length than the first and third line patterns LP1 and LP3. The second line pattern LP2 may extend to the contact region CT.

Subsequently, a first sacrificial layer 34 may be formed in the trench T. The first sacrificial layer 34 may include doped polysilicon, undoped polysilicon, or the like. Before the first sacrificial layer 34 is formed, a second sacrificial layer 33 may be formed on an inner surface of the trench T. The second sacrificial layer 33 may include a material having a high etch selectivity with respect to the first sacrificial layer 34. The second sacrificial layer 33 may include at least one of oxide, nitride, titanium (Ti), titanium nitride (TiN) and metal. For example, after the second sacrificial layer 33 is formed along the entire surface of the first conductive layer 32 including the trench T, a first sacrificial layer 34 may be formed on the first conductive layer 32 to fill the trench T. Subsequently, a planarization process may be formed until the surface of the first conductive layer 32 is exposed. Therefore, the first and second sacrificial layers 34 and 33 may be formed in the trench T.

Referring to FIGS. 3A to 3C, a lower structure may be formed on the first conductive layer 32. The lower structure may include one or more first material layers 35 and one or more second material layers 36 stacked alternately with each other. The first material layer 35 may be stacked to form a gate electrode of a lower selection transistor, and the second material layer 36 may be formed to insulate the stacked gate electrodes from each other.

The first material layer 35 may include a high etch selectivity with respect to the second material layer 36. For example, the first material layer 35 may include a sacrificial layer including a nitride, and the second material layer 36 may include an insulating layer including an oxide. In another example, the first material layer 35 may include a conductive layer including doped polysilicon, doped amorphous silicon, or the like. The second material layer 36 may include an insulating layer including an oxide. According to an embodiment, the first material layer 35 may include a sacrificial layer, and the second material layer 36 may include an insulating layer.

Subsequently, first slits SL1 may pass through the lower structure, and second insulating layers 37 may be formed in the first slits SL1. The second insulating layer 37 may be a first slit insulating layer which patterns the lower structure. The second insulating layer 37 may be located between the trenches T in the contact region CT, and have a linear shape extending in the second direction II-II′. In addition, a portion of the second insulating layer 37 may overlap the trench T in the cell region C, more particularly, the second line pattern LP2 in the trench T (see reference character D).

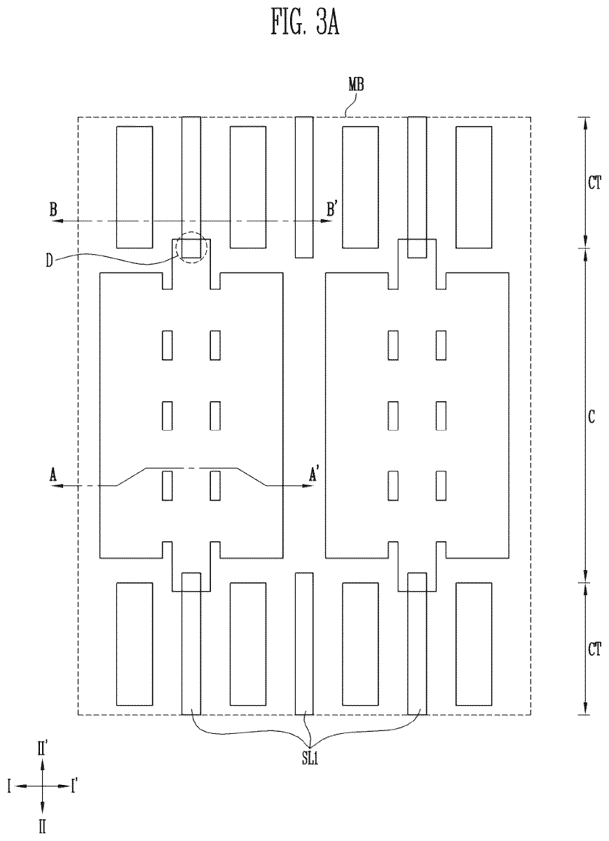

Referring to FIGS. 4A and 4B, an upper structure may be formed on the lower structure to form the structure ST. The upper structure may include the first material layers 35 and the second material layers 36 stacked alternately with each other. At least one uppermost first material layer 35 may be stacked to form a gate electrode of an upper selection transistor, and the other first material layers 35 may be stacked to form gate electrodes of memory cells. In addition, the second material layers 36 may be formed to insulate the stacked gate electrodes from each other. The uppermost second material layer 36 may have a greater thickness than the other second material layers 36.

Subsequently, first openings OP1 may be formed through the structure ST. The first openings OP1 may be located on the trench T in the cell region C, and more particularly, on the first and third line patterns LP1 and LP3. The first openings OP1 may be deep enough to extend to the first sacrificial layer 34 and have various cross-sections such as circular, rectangular, polygonal and elliptical cross-sections.

Subsequently, multilayer dielectric layers 38 may be formed in the first openings OP1. The multilayer dielectric layer 38 may be a memory layer of a memory cell, or a gate insulating layer of a selection transistor. For example, the multilayer dielectric layer 38 may include a tunnel insulating layer, a data storage layer and a charge blocking layer. The data storage layer may include silicon, nitride, nanodots, a phase-change material or the like.

In addition, pillars 39 may be formed in the first openings OP1 in which the multilayer dielectric layers 38 are formed. Gap-filling insulating layers 40 may be formed in open central portions of the pillars 39. The pillars 39 may be arranged in a matrix format at a predetermined distance, or a zigzag pattern. Subsequently, the second material layer 36 may be additionally formed on the structure ST to cover the multilayer dielectric layer 38 and the pillar 39 exposed on a top surface of the structure ST.

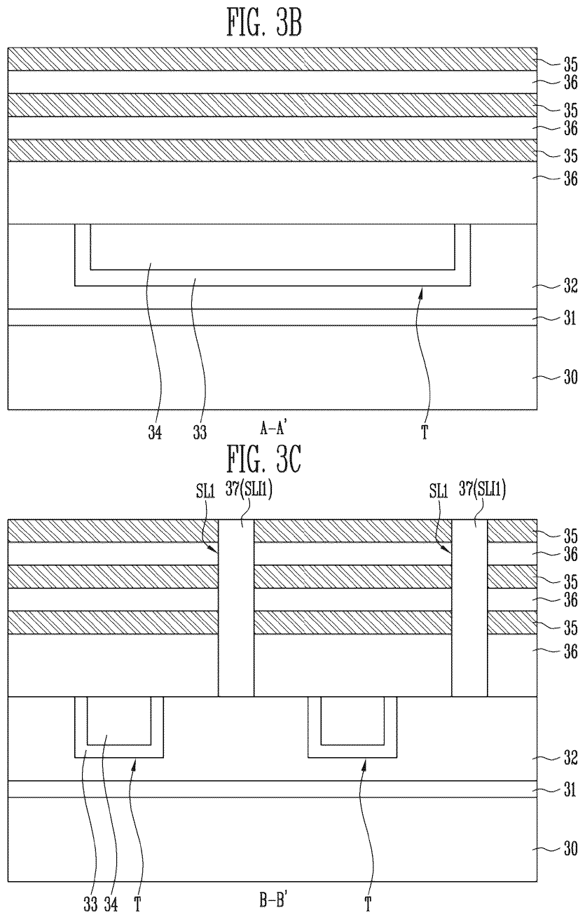

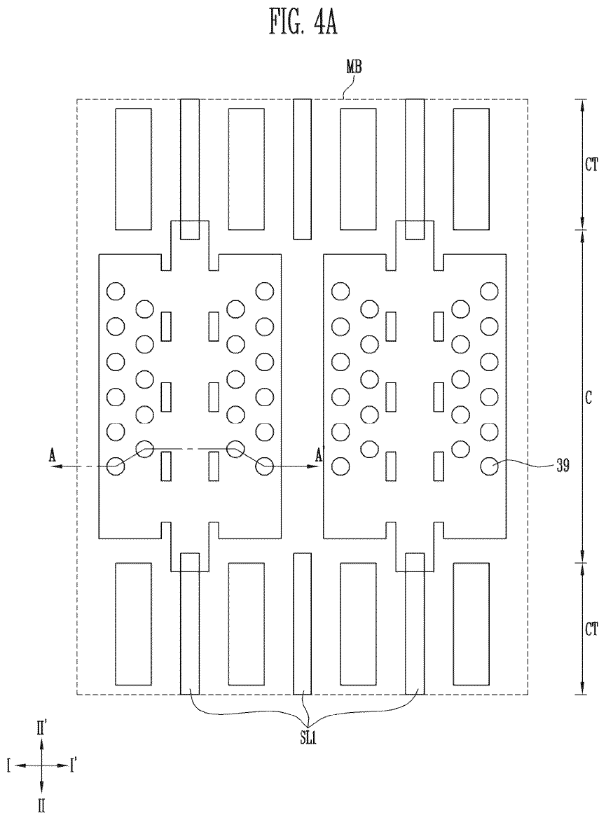

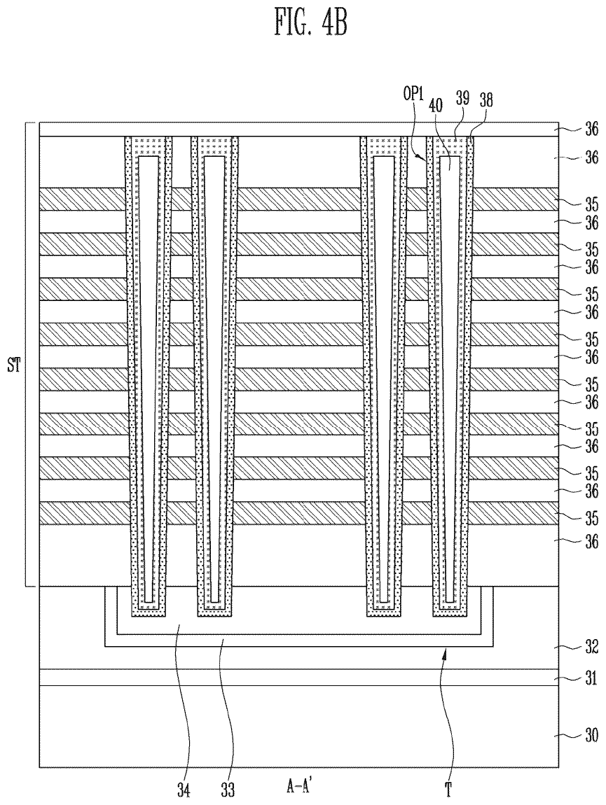

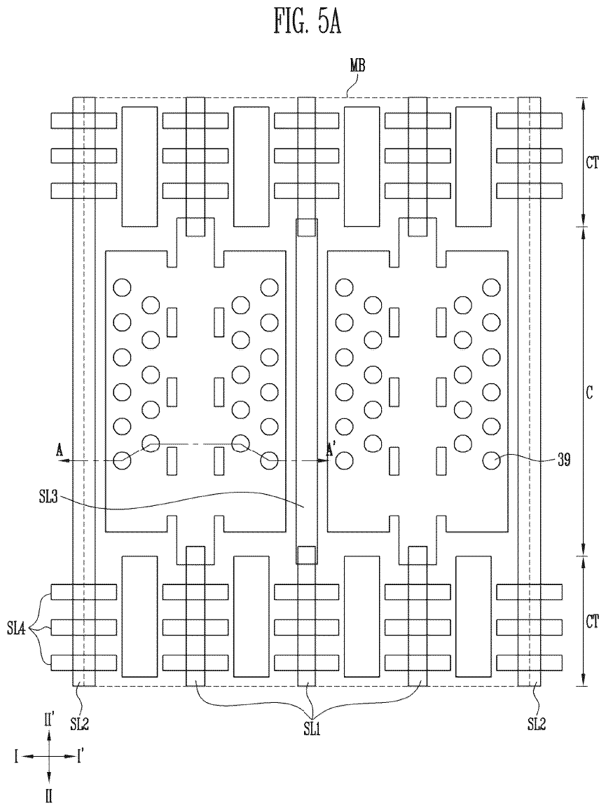

Referring to FIGS. 5A and 5B, at least one of the second, third and fourth slits SL2, SL3 and SL4 may be formed. The second slit SL2 may be formed at the boundary between neighboring memory blocks MB, the third slit SL3 may be located between neighboring trenches T in the cell region C, and the fourth slit SL4 may be located in the contact region CT. Subsequently, third insulating layers 41 may be formed in the second to fourth slits SL2 to SL4. The third insulating layers 41 may function as a support body during subsequent processes of removing the first material layers 35.

The second slit SL2 may separate the structures ST of the neighboring memory blocks MB, may be located in the cell region C and the contact region CT, and have a linear shape extending in the second direction II-II′. The second slit SL2 may be formed through the structure ST and extend to the first conductive layer 32. In addition, the third insulating layer 41 formed in the second slit SL2 may be a second slit insulating layer.

The third slit SL3 may be deep enough to pass through the structure ST and extend to the first conductive layer 32. The third slit SL3 may have a linear shape extending in the second direction II-II′ and overlap with the first slit SL1. In addition, the third insulating layer 41 formed in the third slit SL3 may be a third slit insulating layer and be coupled to the first slit insulating layer formed in the first slit SL1. Therefore, the upper portion of the structure ST may be patterned by the third slit insulating layer only in the cell region C, while the lower portion of the structure ST may be patterned by the first slit insulating layer and the third slit insulating layer in the cell region C and the contact region CT.

The fourth slits SL4 may be located in the contact region CT and be deep enough to pass through the structure ST. The fourth slit SL4 may extend in a first direction I-I′ to cross the first or second slit SL1 or SL2, and have various shapes, such as a linear shape or an island shape. The third insulating layer 41 formed in the fourth slit SL4 may be a fourth slit insulating layer.

Referring to FIGS. 6A to 6C, fifth slits SL5 and sixth slits SL6 may be formed in the cell region C and the contact region CT, respectively.

The fifth slits SL5 may be deep enough to pass through the structure ST. The fifth slits SL5 may be located on the trench T in the cell region C, and more particularly, on the second line pattern LP2, and extend to the first sacrificial layer 34. The fifth slit SL5 may have a width less than or equal to the second line pattern LP2. In addition, the fifth slit SL5 may have a length less than or equal to the second line pattern LP2. The fifth slit SL5 may partially overlap the first slit SL1. Therefore, when the fifth slit SL5 is formed, the first slit insulating layer within the first slit SL1 may be partially etched, and a first slit insulating layer may be exposed through the fifth slit SL5.

The sixth slit SL6 may be deep enough to pass through the structure ST. The sixth slit SL6 may be located on the trench T in the contact region CT and extend to the first sacrificial layer 34. The sixth slit SL6 may have a width less than or equal to that of the trench T. In addition, the sixth slit SL6 may have a length less than or equal to the trench T.

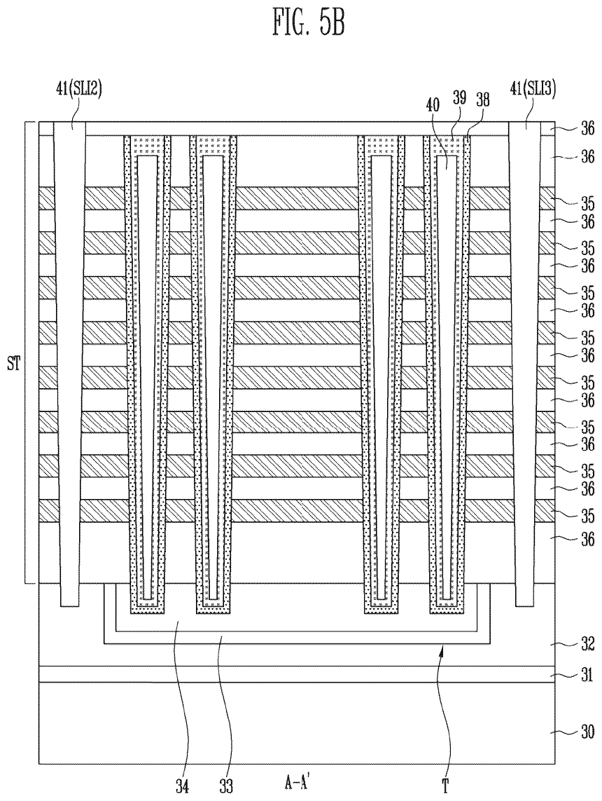

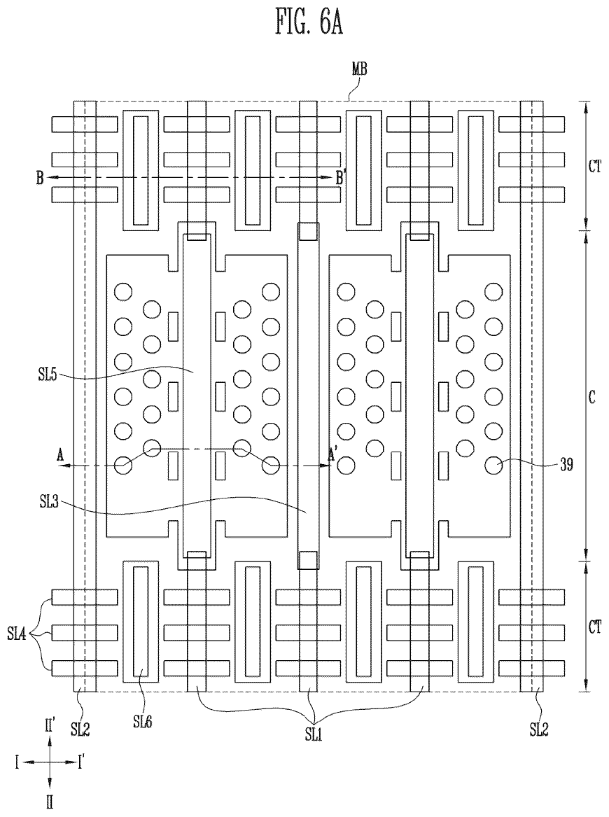

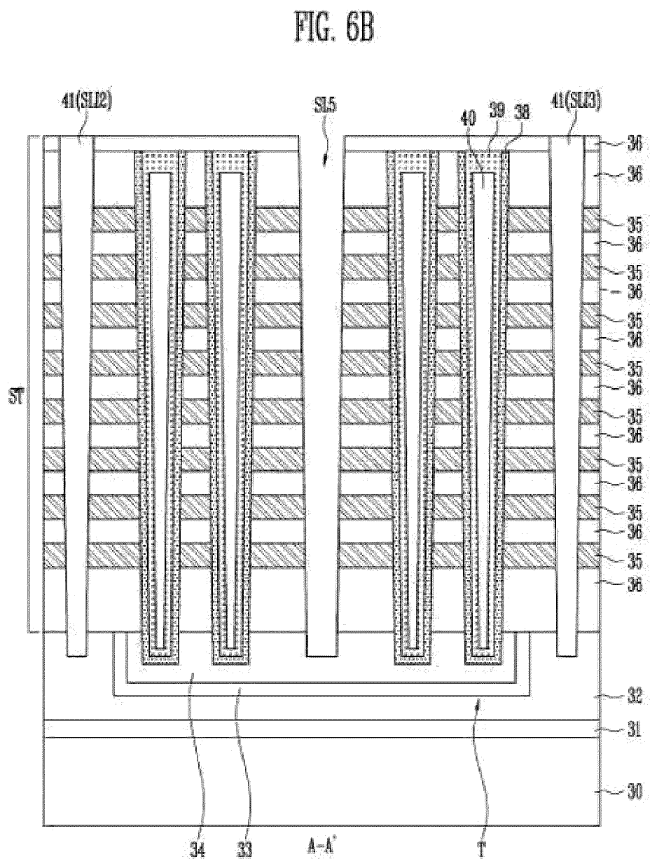

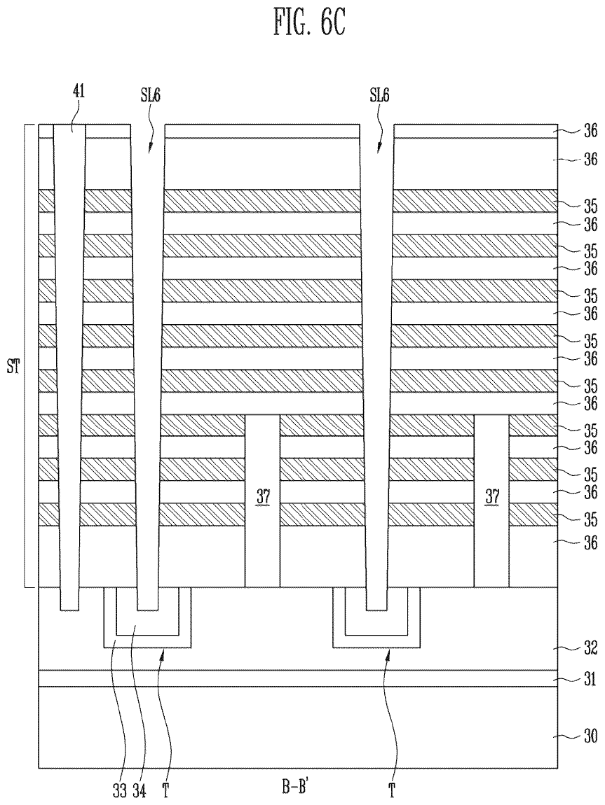

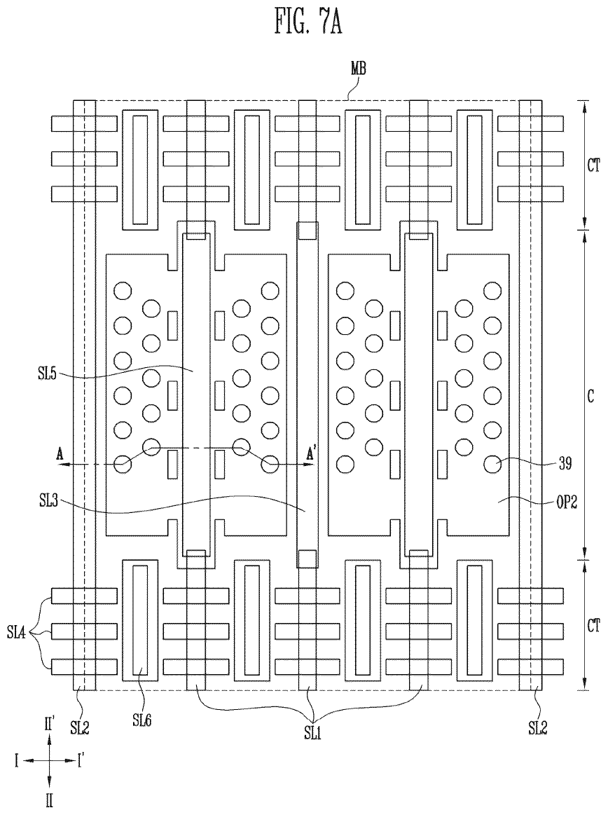

Referring to FIGS. 7A and 7B, the first sacrificial layer 34 and the second sacrificial layer 33 exposed through the fifth slit SL5 may be removed to form second openings OP2. As a result, the multilayer dielectric layer 38 may be partially exposed in the second opening OP2. Subsequently, the multilayer dielectric layer 38 exposed through the second opening OP2 and the first material layers 35 exposed through the fifth and sixth slits SL5 and SL6 may be removed. Third openings OP3 may be formed in regions from which the first material layers 35 are removed. In addition, a lower portion of the pillar 39 may be exposed through the second opening OP2, and the multilayer dielectric layer 38 may be exposed through the third opening OP3.

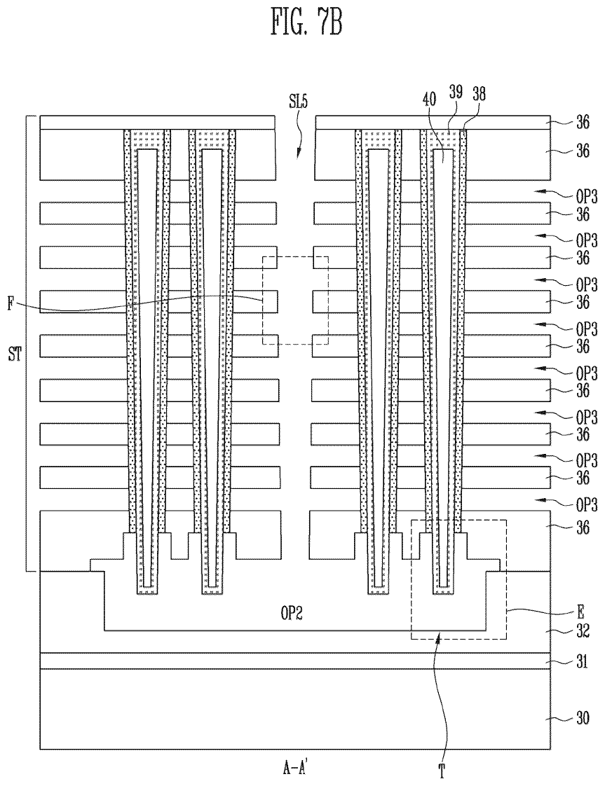

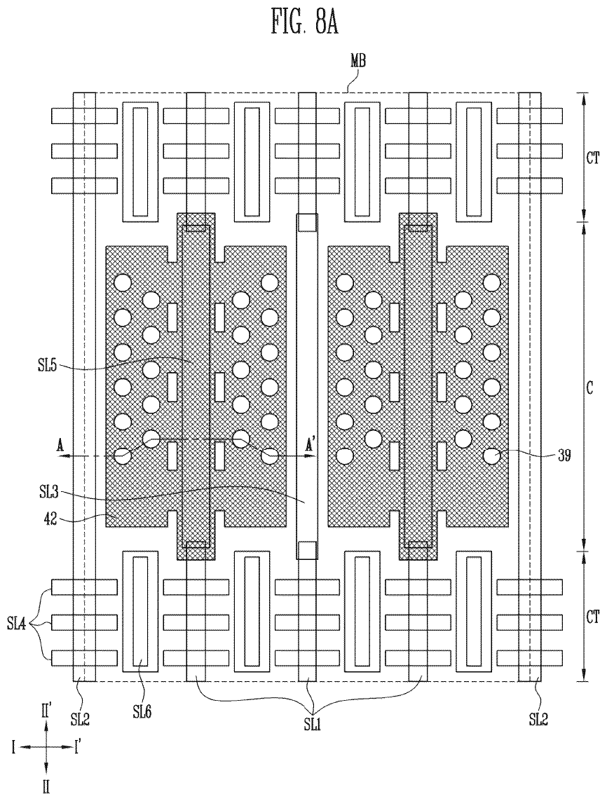

Referring to FIGS. 8A and 8B, second conductive layers 42 may be formed in the second openings OP2. The second conductive layer 42 may include a base portion 42A formed in the trench T and protruding portions 42B protruding from the base portion 42A. The second conductive layer 42 may be a second source layer.

In addition, third conductive layers 43 may be formed in the third openings OP3. The third conductive layers 43 may be gate electrodes of memory cells or selection transistors. Dielectric layers 44 may be formed before the third conductive layers 43 are formed. The dielectric layers 44 may be charge blocking layers.

Subsequently, fourth insulating layers 45 may be formed in the fifth and sixth slits SL5 and SL6. The fourth insulating layer 45 formed in the fifth slit SL5 may be a fifth slit insulating layer, and the fourth insulating layer 45 formed in the sixth slit SL6 may be a sixth slit insulating layer.

Since the fifth slit insulating layer is coupled to the first slit insulating layer, the lower portion of the structure ST may be patterned by the first and fifth slit insulating layer in the cell region C and the contact region CT. The upper portion of the structure ST may be patterned by the fifth slit insulating layer only in the cell region C. Therefore, the third conductive layers 43 included in the lower structure ST may be patterned into a linear shape by the first slit insulating layer, the third slit insulating layer and the fifth slit insulating layer. On the other hand, the third conductive layers 43 included in the upper structure ST may be patterned only in the cell region C. Therefore, different bias may be applied to the third conductive layer 43 located on the left side of the fifth slit or third slit and the third conductive layer 43 located on the right side thereof, among the third conductive layers 43 included in the lower structure ST. On the other hand, the same bias may be applied to the third conductive layer 43 located on the left side of the fifth slit or third slit and the third conductive layer 43 located on the right side thereof, among the third conductive layers 43 included in the upper structure ST.

FIGS. 9A and 9B are cross-sectional views illustrating a method of manufacturing an electronic device according to a modified embodiment. FIG. 9A corresponds to FIG. 4B, and FIG. 9B corresponds to FIG. 8B. Hereinafter, a description of common contents with earlier described embodiments is omitted.

Referring to FIG. 9A, the first opening OP1 may be deep enough to extend to the second sacrificial layer 33. Therefore, the multilayer dielectric layer 38 and the pillar 39 may also be deep enough to extend to the second sacrificial layer 33. In addition, the first opening OP1 may pass through the trench T and extend to the first conductive layer 32. In addition, referring to FIG. 9B, the pillars 39 may be recessed into the second conductive layer 42 deeper than those in the embodiment described above with reference to FIG. 8B.

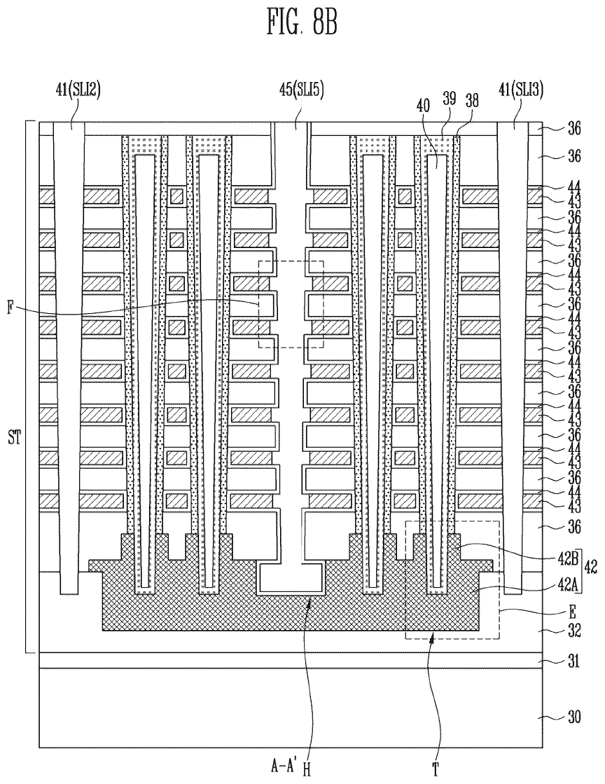

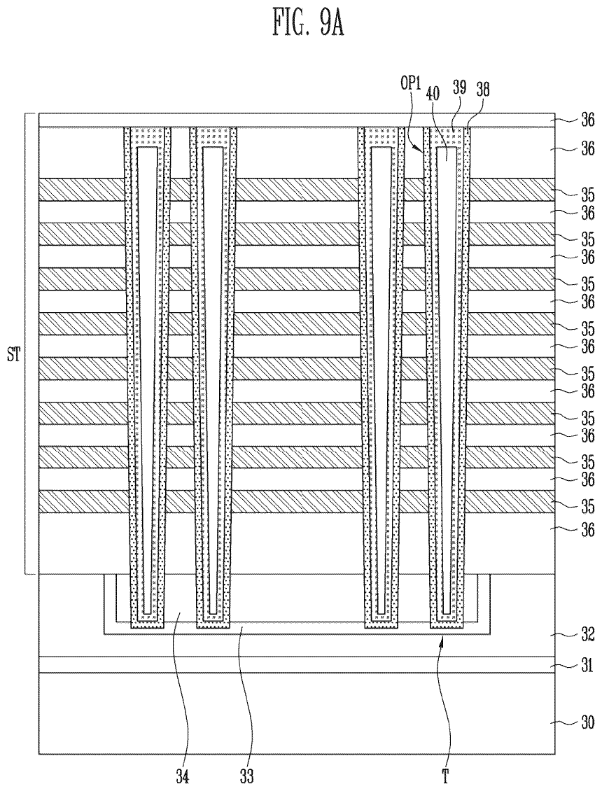

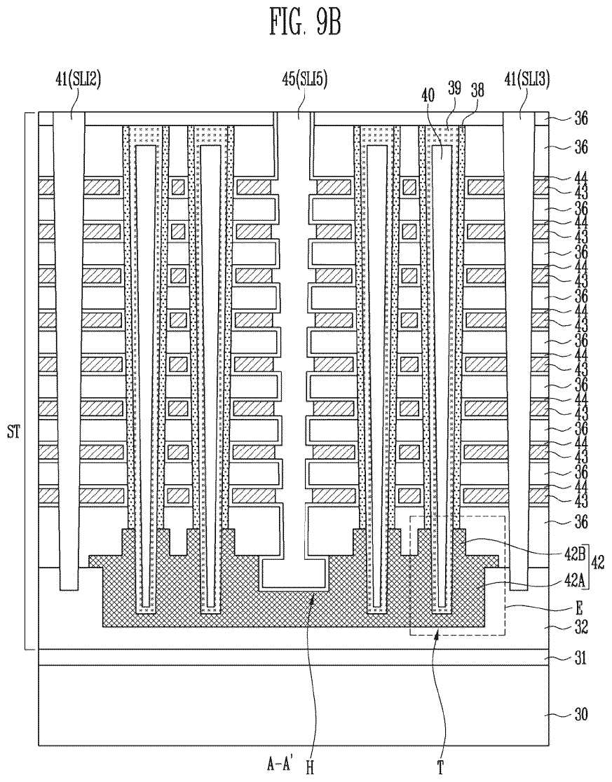

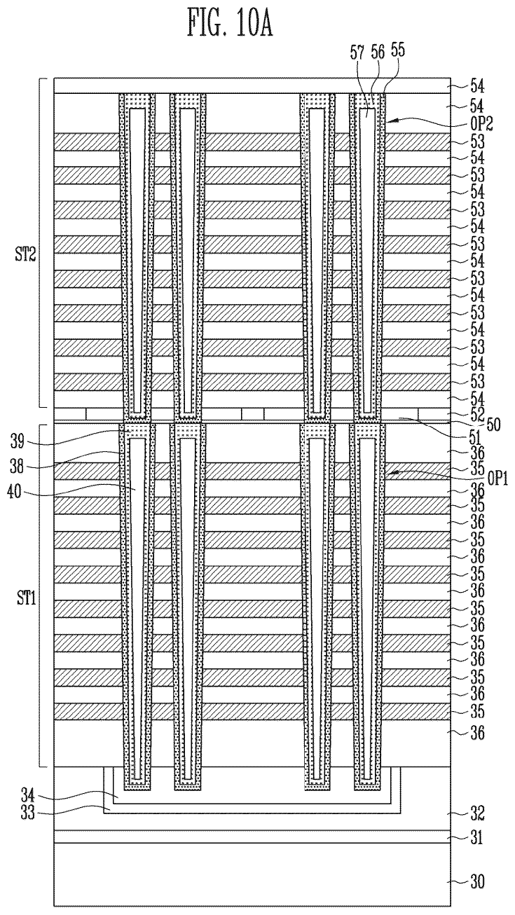

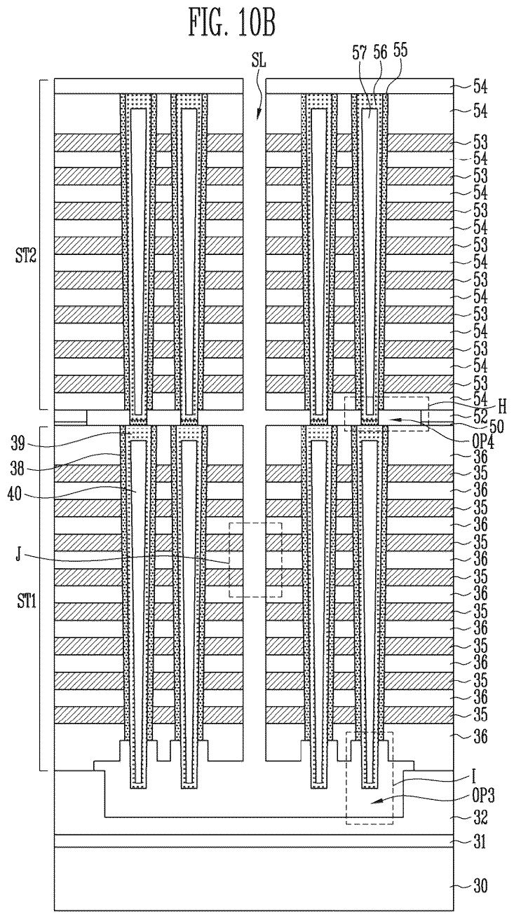

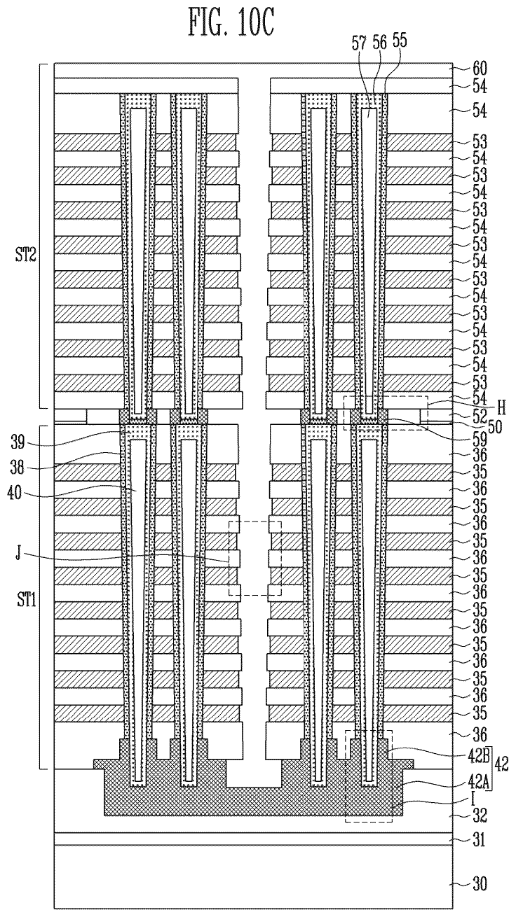

FIGS. 10A to 10C are cross-sectional views illustrating a method for manufacturing an electronic device according to an embodiment. Hereinafter, a description of common contents with earlier described embodiments is omitted.

Referring to FIG. 10A, the first insulating layer 31, the first conductive layer 32, the first sacrificial layer 34 and the second sacrificial layer 33 may be formed over the substrate 30. Subsequently, the first structure ST1 including the first material layers 35 and the second material layers 36 stacked alternately with each other may be formed thereon. The first material layers 35 are conductive layers and the second material layers 36 are insulating layers.

After the first openings OP1 are formed through the first structure ST1, the first multilayer dielectric layers 38, the first pillars 39 and the first gap-filling insulating layers 40 may be formed in the first openings OP1.

Subsequently, a third sacrificial layer 50 and a fourth sacrificial layer 51 may be sequentially formed on the first structure ST1. The fourth sacrificial layer 51 may be formed to ensure spaces in which coupling patterns are formed to couple the first pillars 39 and second pillars to be formed. The fourth sacrificial layer 51 may overlap with at least one first pillar 39. For example, the third sacrificial layer 50 may include an oxide, and the fourth sacrificial layer 51 may include polysilicon.

The fourth sacrificial layer 51 may be formed in the second insulating layer 52. For example, after the second insulating layer 52 is formed on the third sacrificial layer 50, the second insulating layer 52 may be partially etched to form a trench. Subsequently, the fourth sacrificial layer 51 may be formed in the trench. Another second insulating layer 52 may be additionally formed to cover the fourth sacrificial layer 51 and the previously formed second insulating layer 52. In another example, after the third sacrificial layer 50 is formed on the first structure ST1, the fourth sacrificial layer 51 having a desired pattern may be formed on the third sacrificial layer 50. Subsequently, the second insulating layer 52 may be formed on the third sacrificial layer 50 on which the fourth sacrificial layer 51 is formed.

Subsequently, the second structure ST2 including first material layers 53 and second material layers 54 stacked alternately with each other may be formed on the second insulating layer 52. The first material layers 53 may include conductive layers, and the second material layers 54 may include insulating layers.

Subsequently, after the second openings OP2 are formed through the second structure ST2, second multilayer dielectric layers 55, second pillars 56 and second gap-filling insulating layers 57 may be formed in the second openings OP2. The second openings OP2 may be deep enough to partially etch the first pillars 39 so that upper portions of the first pillars 39 and lower portions of the second pillars 56 may overlap with each other. In addition, the second pillars 56 may be formed at positions corresponding to the first pillars 39, respectively.

Referring to FIG. 10B, the slit SL may be formed through the second structure ST2, the second insulating layer 52, the third sacrificial layer 50, the fourth sacrificial layer 51, the first structure ST1 and the first sacrificial layer 34. Subsequently, the first sacrificial layer 34, the second sacrificial layer 33 and the fourth sacrificial layer 51 exposed through the slit SL may be removed to form the third openings OP3 and the fourth openings OP4. As a result, the first multilayer dielectric layer 38 may be partially exposed through the third opening OP3. For example, a lower portion of the first multilayer dielectric layer 38 may be exposed through the third opening OP3. The second multilayer dielectric layer 55 may be partially exposed through the fourth opening OP4. For example, a lower portion of the second multilayer dielectric layer 55 may be exposed through the fourth opening OP4.

Subsequently, the first and second multilayer dielectric layers 38 and 55 exposed through the third and fourth openings OP3 and OP4, respectively, may be removed. As a result, the first pillars 39 may be partially exposed through the third openings OP3. For example, the lower portion of the first pillars 39 may be exposed through the third opening OP3. The second pillars 56 may be partially exposed through the fourth openings OP4. For example, the lower portion of the second pillars 56 may be exposed through the third opening OP4.

Referring to FIG. 10C, the second conductive layer 42 may be formed between the first conductive layer 32 and the first pillars 39 exposed through the third openings OP3. For example, the second conductive layer 42 including silicon may be grown by selective growth. Before the second conductive layer 42 is grown by selective growth, a dry cleaning process may be performed to remove a native oxide layer formed on the first conductive layer 32 and the first pillars 39. After the dry cleaning process is performed, a selective growth process may be directly performed without a vacuum break.

In addition, coupling patterns 59 may be formed between the first pillars 39 and the second pillars 56 exposed through the fourth openings OP4. For example, the coupling patterns 59 may be grown from the first pillars 39, from the second pillars 56, or from both by selective growth. Growth conditions may be controlled so that the neighboring coupling patterns 59 may not be coupled to each other. As a result, the coupling patterns 59 including silicon may be formed. Subsequently, a third insulating layer 60 may be formed in the first opening OP1, the second opening OP2 and the slit SL.

According to the above-described processes, since a pillar having a high aspect ratio is formed using two separate processes, it may be easier to manufacture an electronic device. In addition, the coupling pattern 59 coupling the first pillar 39 and the second pillar 56 may be formed by selective growth after a dry cleaning process is performed, so that contact resistance between the first pillar 39 and the second pillar 56 may be reduced. In addition, since the coupling pattern 59 and the second conductive layer 42 are formed at the same time, manufacturing processes of an electronic device may be simplified.

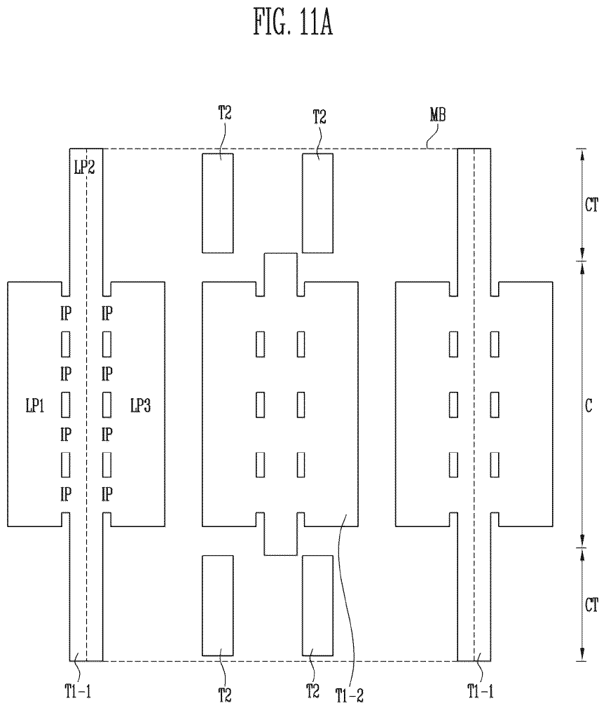

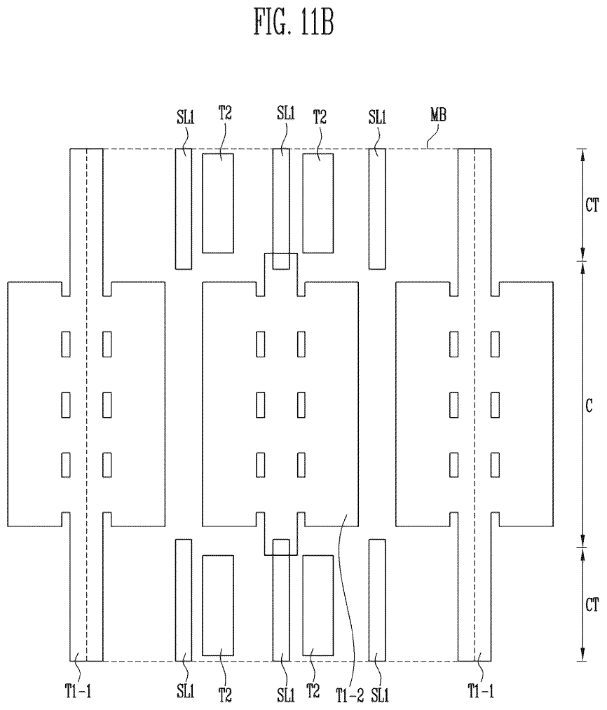

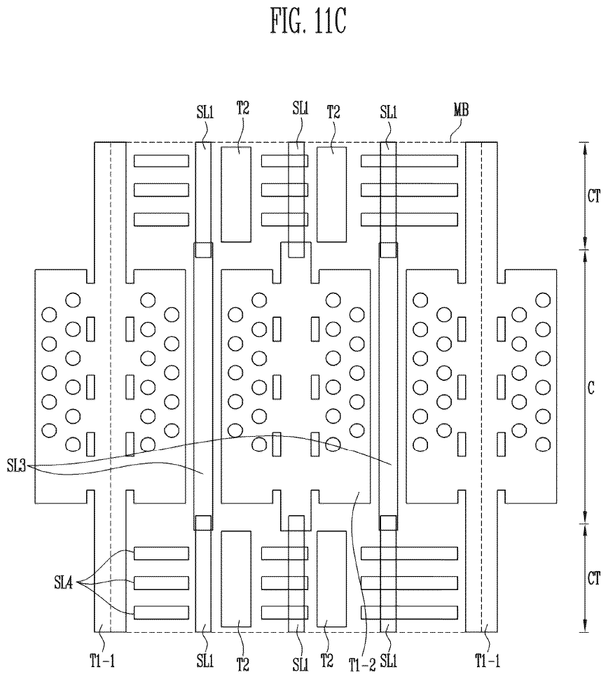

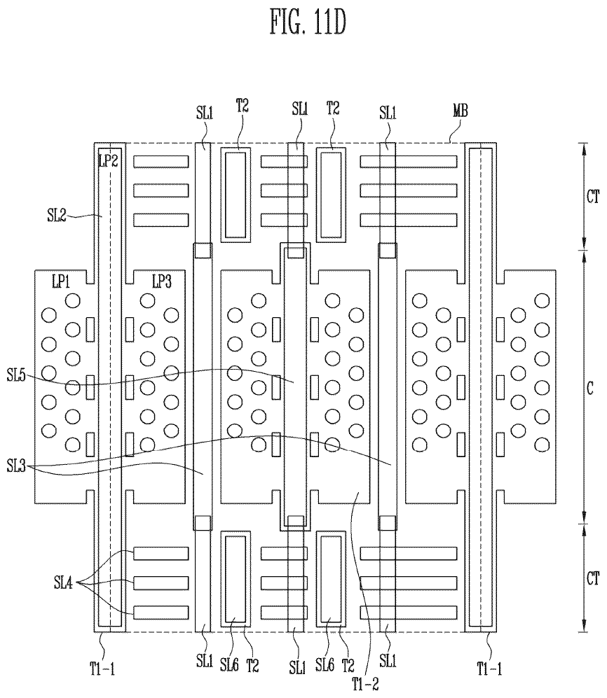

FIGS. 11A to 11D are layout views illustrating the structure of an electronic device according to a modified embodiment. Hereinafter, a description of common contents with earlier described embodiments is omitted, and the layouts are mainly described.

Referring to FIG. 11A, first trenches T1-1 and T1-2 and second trenches T2 may be formed in the cell region C and the contact region CT. More specifically, the first trenches T1-1 and T1-2 may be located in the memory block MB or at the boundary between neighboring memory blocks MB. In addition, the second trenches T2 may be located in the contact region CT.

Each of the first trenches T1-1 and T1-2 may include the first to third line patterns LP1 to LP3 and island patterns IP coupling the line patterns LP1 to LP3. The first trenches T1-1 and T1-2 may have the same or different shapes, and may include the second line patterns LP2 having different lengths. For example, the second line pattern LP2 of a first type-first trench T1-1 may have a greater length than a second type-first trench T1-2. The second line pattern LP2 of the first type-first trench T1-1 may extend from the cell region C to the contact region CT and separate the first conductive layers 32 of the neighboring memory blocks MB from each other.

Referring to FIG. 11B, the first slits SL1 may be formed in the contact region CT and pass through the lower structure. The first slits SL1 may be located between the second trenches T2. Some of the first slits SL1 may overlap with the second type-first trench T1-2. For example, a first end of the first slits SL1 may overlap with a first end of the second type-first trench T1-2. First slit insulating layers may be formed in the first slits SL1.

Referring to FIG. 11C, the third slits SL3 may be formed between the neighboring first trenches T1-1 and T1-2 in the cell region C, and the fourth slits SL4 may be formed in the contact region CT.

The third slit SL3 may be deep enough to pass through the structure ST and expose the first slit insulating layer. Therefore, a third slit insulating layer formed in the third slit SL3 may be coupled to the first slit insulating layer.

The fourth slits SL4 may be located between the first and second trenches T1-1, T1-2, and T2 and have the same lengths or different lengths from each other. In addition, some of the fourth slits SL4 may cross the first slit SL1. Fourth slit insulating layers may be formed in each of the fourth slits SL4.

Referring to FIG. 11D, the second slits SL2 may be formed at the boundary between the neighboring memory blocks MB, the fifth slits SL5 may be formed in the cell region C, and the sixth slits SL6 may be formed in the contact region CT.

The second slit SL2 may be deep enough to pass through the structure ST and be formed on the second line pattern LP2 of the first type-first trench T1-1. The second slit SL2 may have a smaller width and length than the second line pattern LP2.

The fifth slit SL5 may be deep enough to pass through the structure ST and be located on the second line pattern LP2 of the second type-first trench T1-2. In addition, the fifth slit SL5 may overlap with the first slit SL1.

The sixth slits SL6 may be located on the second trenches T2 and have a smaller width and length than the second trench T2.

According to the above-described layout, the first and second sacrificial layers 34 and 33 may be replaced with the second conductive layer 42, and the first material layers 35 may be replaced with the third conductive layers 43, through the second, fifth and sixth slit SL2, SL5, and SL6. In addition, second, fifth and sixth slit insulating layers may be formed in the second, fifth and sixth slits SL2, SL5, and SL6, and the fifth slit insulating layer may be coupled to the first slit insulating layer. The shapes, arrangements and formation order of the slits may vary.

FIGS. 12A to 16A and FIGS. 12B to 16B are views illustrating a method of manufacturing an electronic device according to an embodiment. More specifically, FIGS. 12A to 16A are enlarged views of the region E shown in FIGS. 7B and 8B, and FIGS. 12B to 16B are enlarged views of the region F shown in FIGS. 7B and 8B.

Referring to FIGS. 12A and 12B, the multilayer dielectric layer 38 may include a first dielectric layer 38A, a second dielectric layer 38B and a third dielectric layer 38C. The first dielectric layer 38A may be formed along an inner surface of the first opening OP1. The second dielectric layer 38B may be formed on the first dielectric layer 38A and have a high etch selectivity with respect to the first dielectric layer 38A. The third dielectric layer 38C may be formed on the second dielectric layer 38B and have a high etch selectivity with respect to the second dielectric layer 38B. For convenience of description, the first, second and third dielectric layers may be referred to as a charge blocking layer 38A, a data storage layer 38B and a tunnel insulating layer 38C, respectively, according to functions thereof.

After the charge blocking layer 38A, the data storage layer 38B and the tunnel insulating layer 38C are sequentially formed in the first opening OP1, the pillar 39 and the gap-filling insulating layer 40 may be formed therein. Subsequently, the first sacrificial layer 34 may be removed through the fifth slit SL5 to form the second opening OP2. As a result, the charge blocking layer 38A may be exposed through the second opening OP2.

Referring to FIGS. 13A and 13B, the charge blocking layer 38A exposed through the second opening OP2 may be removed, so that the data storage layer 38B may be exposed through the second opening OP2. When the charge blocking layer 38A and the second material layers 36 include oxides, the second material layers 36 exposed through the fifth slit SL5 may be etched to a predetermined thickness during an etching process of the charge blocking layer 38A. The first material layers 35 may protrude further than the second material layers 36. As a result, irregularities may be formed on inner walls of the second slit SL2, the fifth slit SL5 and the sixth slit SL6.

In addition, when the charge blocking layer 38A, the second material layers 36 and the second sacrificial layer 33 include oxides, the second sacrificial layer 33 and the second material layer 36 exposed through the second opening OP2 may be etched to a predetermined thickness during the etching process of the charge blocking layer 38A. Therefore, the second opening OP2 may be extended.

Referring to FIGS. 14A and 14B, the data storage layer 38B exposed through the second opening OP2 may be removed, so that the tunnel insulating layer 38C may be exposed through the second opening OP2. The data storage layer 38B may be removed to a greater depth than the charge blocking layer 38A. In addition, since the data storage layer 38B is removed, the second opening OP2 may be extended in a vertical direction.

When the data storage layer 38B and the first material layers 35 include nitrides, the first material layers 35 may be etched during an etching process of the second data storage layer 38B. Therefore, the third openings OP3 may be formed in regions from which the first material layers 35 are removed.

Referring to FIGS. 15A and 15B, the tunnel insulating layer 38C exposed through the second opening OP2 may be removed. The charge blocking layer 38A exposed through the second opening OP2 may also be removed. The tunnel insulating layer 38C and the charge blocking layer 38A may be removed to substantially the same depth as the data storage layer 38B is removed. As a result, the pillar 39 may be exposed through the second opening OP2. When the tunnel insulating layer 38C and the second material layers 36 include oxides, the second material layers 36 may be partially etched during the etching process of the tunnel insulating layer 38C.

In addition, the remaining second sacrificial layer 33 may be completely removed to expose the first conductive layer 32 through the second opening OP2. When the tunnel insulating layer 38C is removed, the charge blocking layer 38A exposed through the third openings OP3 may be removed partially or completely. However, the function of the charge blocking layer 38A may be complemented by additionally forming the dielectric layer 44 before the third conductive layer 43 is formed. See FIGS. 16A and 16B.

Referring to FIGS. 16A and 16B, the second conductive layer 42 may be formed between the first conductive layer 32 and the pillar 39 exposed through the second opening OP2. For example, the second conductive layer 42 may be formed by growing doped polysilicon from the first conductive layer 32, from the pillar 39, or both by selective growth. The doped polysilicon may be selectively grown in the second opening OP2, and the doped polysilicon may not be grown in the third opening OP3. In another example, the second conductive layer 42 may be formed by depositing doped polysilicon in the second opening OP2. In this example, the doped polysilicon may be partially deposited in the third opening OP3 as well as the second opening OP2. In another example, the second conductive layer 42 may be formed by siliciding the first conductive layer 32 and the pillar 39 exposed through the second opening OP2. After the first conductive layer 32 and the pillar 39 are doped with impurities, a metal layer may be formed thereon. Subsequently, a silicide layer may be formed through reaction between the metal layer and an impurity-doped region.

After the dielectric layer 44 is formed along inner surfaces of the second slit SL2, the fifth slit SL5, the sixth slit SL6 and the third openings OP3, the third conductive layers 43 may be formed in the third openings OP3. Subsequently, the fourth insulating layer 45 may be formed in the second slit SL2, the fifth slit SL5 and the sixth slit SL6.

In the electronic device described with reference to FIGS. 10A to 10C, the second conductive layer 42 and the coupling pattern 59 may be formed by applying the manufacturing method described above. For example, selective growth may be performed to form the second conductive layer 42 and the coupling pattern 59 including silicon.

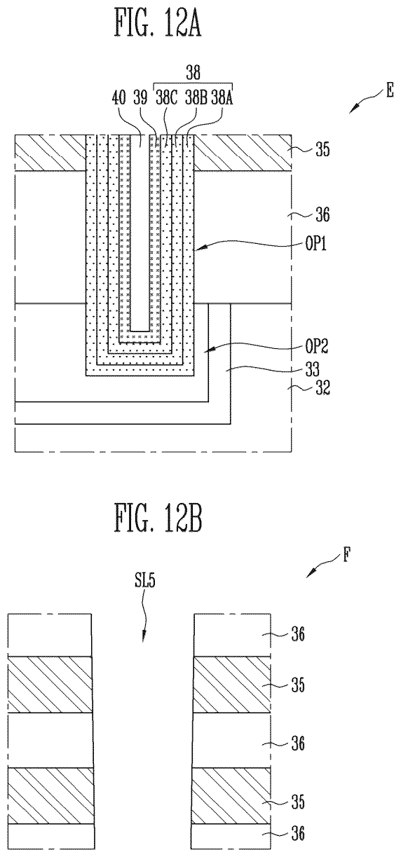

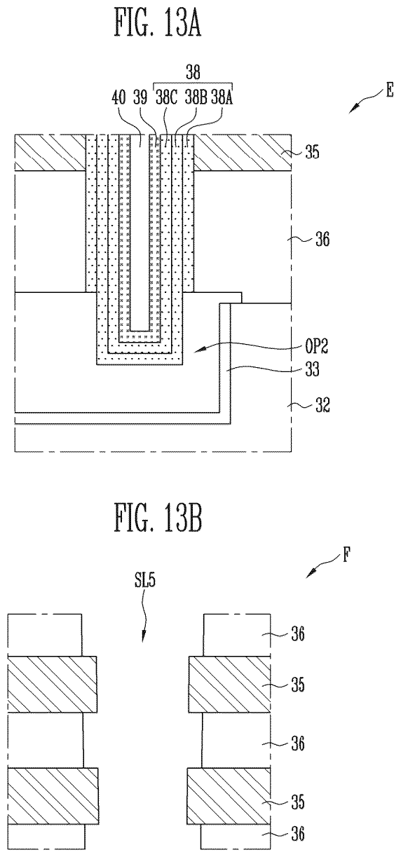

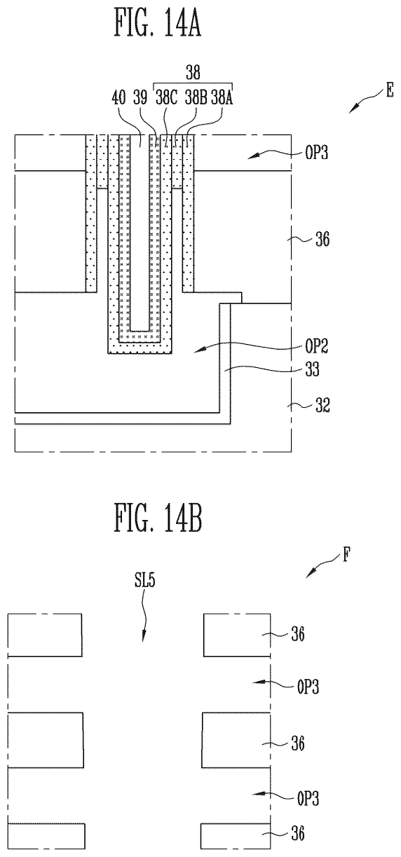

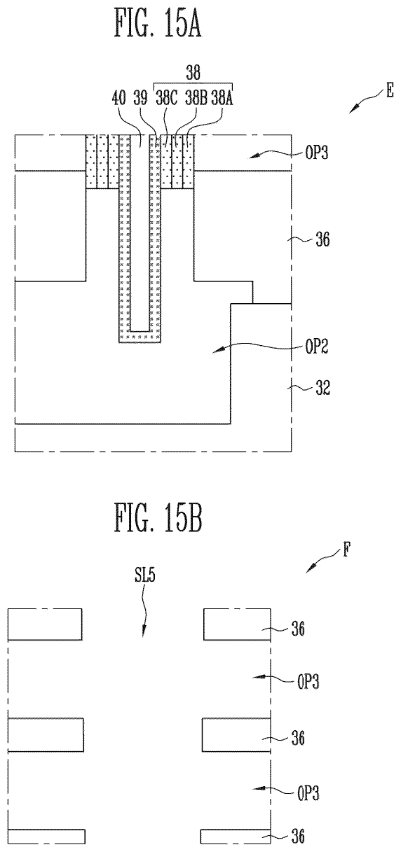

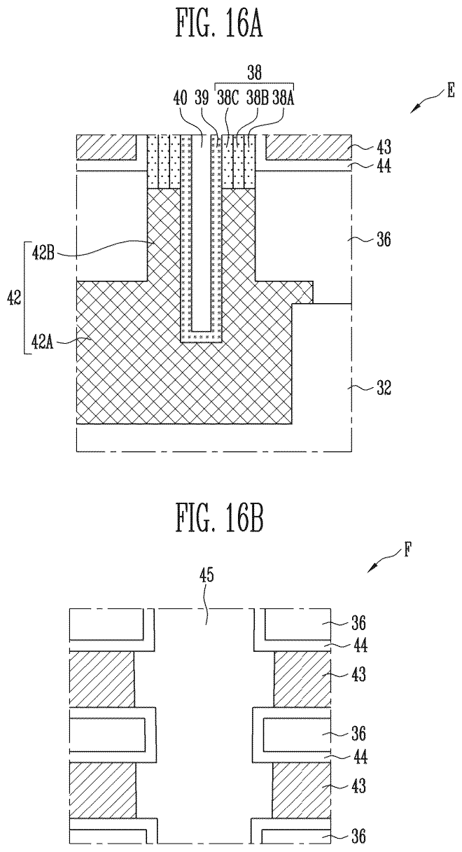

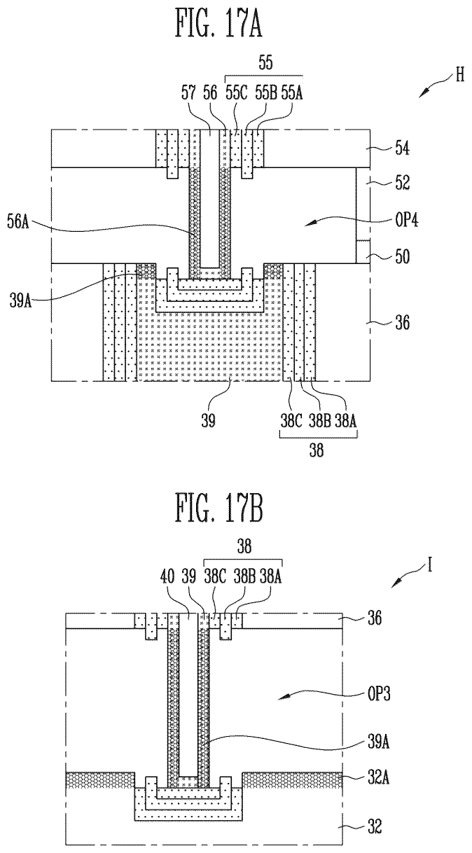

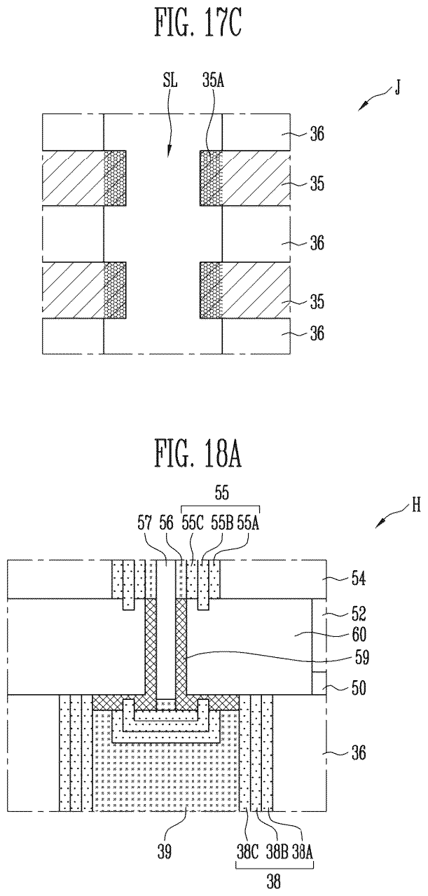

FIGS. 17A to 17C and 18A to 18C are enlarged views illustrating a method of manufacturing an electronic device according to an embodiment. More specifically, FIGS. 17A and 18A correspond to the region H shown in FIGS. 10B and 10C, FIGS. 17B and 18B correspond to the region I shown in FIGS. 10B and 10C, and FIGS. 17C and 18C correspond to the region J shown in FIGS. 10B and 10C. Hereinafter, a description of common contents with earlier described embodiments is omitted.

Referring to FIGS. 17A to 17C, the first multilayer dielectric layer 38, the first sacrificial layer 34 and the second sacrificial layer 33 exposed through the third opening OP3 may be removed. In addition, the second multilayer dielectric layer 55, the third sacrificial layer 50 and the fourth sacrificial layer 51 exposed through the fourth opening OP4 may be removed, so that the first pillar 39 and the first conductive layer 32 may be exposed through the third opening OP3, and the first pillar 39 and the second pillar 56 may be exposed through the fourth opening OP4.

When the first material layer 35 includes a conductive layer such as a doped silicon layer, the first material layer 35 may not be removed when first and second data storage layers 38B and 55B are removed. In addition, when the first and second tunnel insulating layers 38C and 55C and the first and second charge blocking layers 38A and 55A are removed, the second material layers 36 may be removed. As a result, an inner wall of the slit SL may be formed unevenly and the first material layers 35 may protrude.

Subsequently, the first pillar 39, the second pillar 56 and the first conductive layer 32 exposed by removing the second material layers 36 may be doped with impurities. For example, a heat treatment process may be performed in a gas atmosphere containing an impurity such as PH₃ gas, or plasma doping using N type impurities such as As or P may be performed. As a result, impurity-doped regions 39A, 56A, and 32A may be formed. An impurity-doped region 35A may be formed in each of the first material layers 35.

Referring to FIGS. 18A to 18C, the impurity-doped region 39A, 56A, and 32A may be silicided to form the second conductive layer 42 and the coupling pattern 59. For example, a metal layer may be formed on the impurity-doped regions 39A, 56A, and 32A through the slit SL and the third and fourth openings OP3 and OP4. The metal layer may include cobalt, nickel, and the like. Subsequently, the impurity-doped regions 39A, 56A, and 32A may be reacted with the metal layer and silicided, so that the second conductive layer 42 and the coupling pattern 59 including the silicide layer may be formed. In addition, when the first material layers 35 include polysilicon, a silicide layer 35B may also be formed in the impurity-doped region 35A of each of the first material layers 35.

The impurity-doped region 39A formed at the first pillar 39 and the impurity-doped region 32A formed at the first conductive layer 32 may be coupled to each other during silicidation to form the second conductive layer 42. In addition, the impurity-doped region 39A formed at the first pillar 39 and the impurity-doped region 56A formed at the second pillar 56A may be coupled to each other during silicidation to form the coupling pattern 59.

FIG. 19 is a block diagram illustrating a memory system according to an embodiment.

As illustrated in FIG. 19, a memory system 1000 according to an embodiment may include a memory device 1200 and a controller 1100.

The memory device 1200 may be used to store various types of data such as text, graphic, and software code. The memory device 1200 may be a non-volatile memory and include the structure described above and shown in FIGS. 1A to 18C. The memory device 1200 may include a first source layer including a trench, a second source layer formed in the trench, a structure including a plurality of conductive layers and a plurality of insulating layers formed alternately on the first and second source layers, and a plurality of channel layers passing through the structure and extending into the second source layer, in which the second source layer includes a base portion electrically connecting the channel layers adjacent to each other and a plurality of protruding portions protruding from the base portion, extending into the structure and partially surrounding the plurality of channel layers. Since the memory device 1200 is configured and manufactured in the above-described manner, a detailed description thereof will be omitted.

The controller 1100 may be coupled to a host and the memory device 1200, and may access the memory device 1200 in response to a request from the host. For example, the controller 1100 may control read, write, erase and background operations of the memory device 1200.

The controller 1100 may include a random access memory (RAM) 1110, a central processing unit (CPU) 1120, a host interface 1130, an error correction code (ECC) circuit 1140 and a memory interface 1150.

The RAM 1110 may function as an operation memory of the CPU 1120, a cache memory between the memory device 1200 and the host, and a buffer memory between the memory device 1200 and the host. The RAM 1110 may be replaced with a static random access memory (SRAM) or a read only memory (ROM).

The CPU 1120 may be configured to control the general operation of the controller 1100. For example, the CPU 1120 may be configured to operate firmware such as a flash translation layer (FTL) stored in the RAM 1110.

The host interface 1130 may interface with the host. For example, the controller 1100 may communicate with the host through various interface protocols including a Universal Serial Bus (USB) protocol, a multimedia card (MMC) protocol, a peripheral component interconnection (PCI) protocol, a PCI-express (PCI-E) protocol, an Advanced Technology Attachment (ATA) protocol, a Serial-ATA protocol, a Parallel-ATA protocol, a small computer small interface (SCSI) protocol, an enhanced small disk interface (ESDI) protocol, an Integrated Drive Electronics (IDE) protocol, a private protocol, or a combination thereof.

The ECC circuit 1140 may detect and correct errors included in data, which is read from the memory device 1200, by using error correction codes (ECCs).

The memory interface 1150 may interface with the memory device 1200. For example, the memory interface 1150 may include a NAND interface or a NOR interface.

For example, the controller 1100 may further include a buffer memory (not illustrated) configured to temporarily store data. The buffer memory may temporarily store data externally transferred through the host interface 1130, or temporarily store data transferred from the memory device 1200 through the memory interface 1150. The controller 1100 may further include a read only memory (ROM) storing code data to interface with the host.

Since the memory system 1000 according to an embodiment includes the memory device 1200 allowing for easy manufacture and having improved characteristics, characteristics of the memory system 1000 may also be improved.

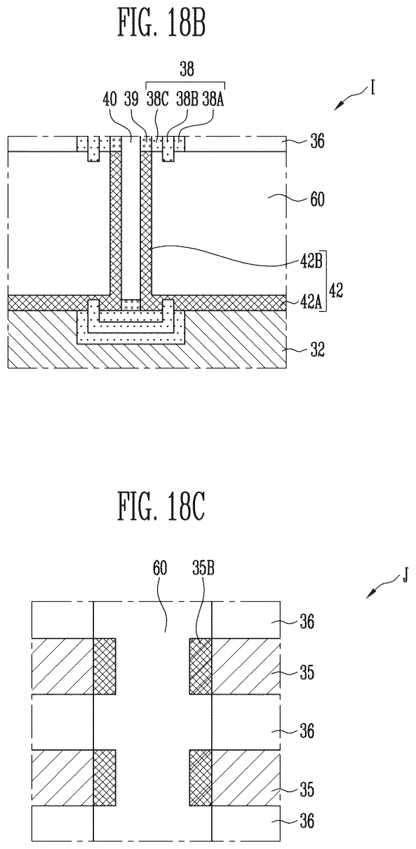

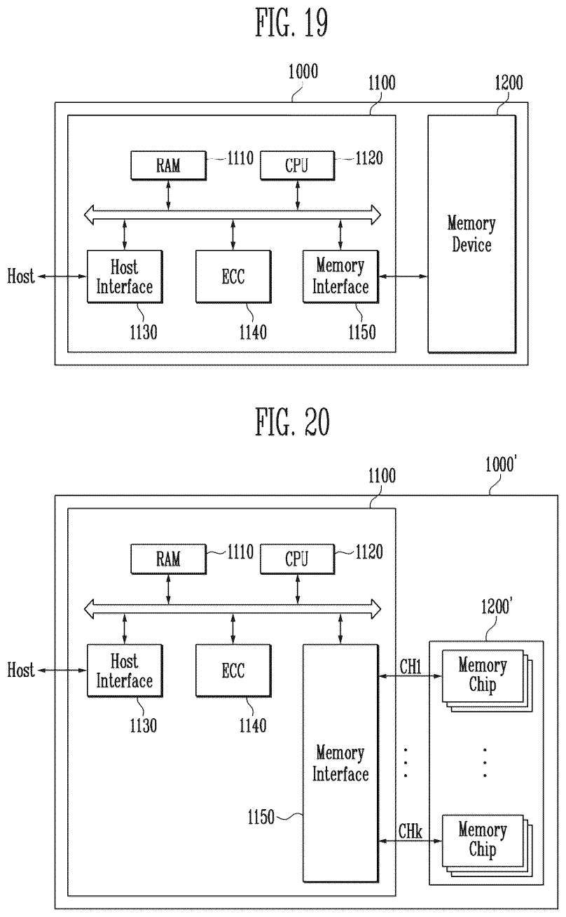

FIG. 20 is a block diagram illustrating a memory system according to an embodiment. Hereinafter, descriptions of components already mentioned above are omitted.

As illustrated in FIG. 20, a memory system 1000′ according to an embodiment may include a memory device 1200′ and the controller 1100. The controller 1100 may include the RAM 1110, the CPU 1120, the host interface 1130, the ECC circuit 1140 and the memory interface 1150.

The memory device 1200′ may be a non-volatile memory device. The memory device 1200′ may include a first source layer including a trench, a second source layer formed in the trench, a structure including a plurality of conductive layers and a plurality of insulating layers formed alternately on the first and second source layers, and a plurality of channel layers passing through the structure and extending into the second source layer, in which the second source layer includes a base portion electrically connecting the channel layers adjacent to each other and a plurality of protruding portions protruding from the base portion, extending into the structure and partially surrounding the plurality of channel layers. Since the memory device 1200′ is configured and manufactured in the same manner as the memory devices 1200, a detailed description thereof will be omitted.

The memory device 1200′ may be a multi-chip package composed of a plurality of memory chips. The plurality of memory chips may be divided into a plurality of groups. The plurality of groups may communicate with the controller 1100 through first to k-th channels CH1 to CHk. In addition, memory chips included in a single group may be suitable for communicating with the controller 1100 through a common channel. The memory system 1000′ may be modified so that a single memory chip may be coupled to a single channel.

As described above, according to an embodiment, since the memory system 1000′ includes the memory device 1200′ having improved structural stability, characteristics of the memory system 1000′ may also be improved. In addition, since the memory device 1200′ is formed using a multi-chip package, data storage capacity and driving speed of the memory system 1000′ may be further increased.

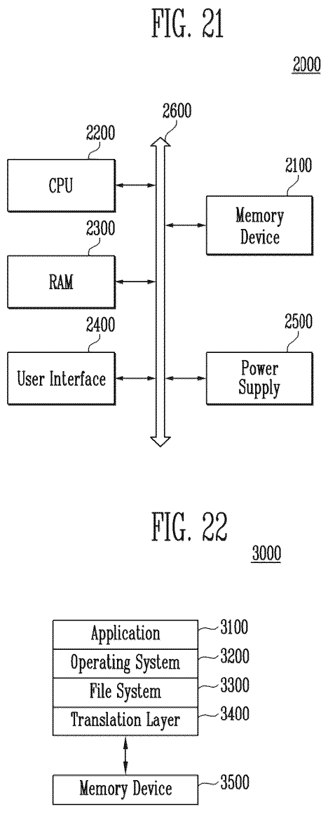

FIG. 21 is a block diagram illustrating a computing system according to an embodiment. Hereinafter, descriptions of components already mentioned above are omitted.

As illustrated in FIG. 21, a computing system 2000 according to an embodiment may include a memory device 2100, a CPU 2200, a random-access memory (RAM) 2300, a user interface 2400, a power supply 2500 and a system bus 2600.

The memory device 2100 may store data, which is input through the user interface 2400, and data, which is processed by the CPU 2200. The memory device 2100 may be electrically coupled to the CPU 2200, the RAM 2300, the user interface 2400, and the power supply 2500. For example, the memory device 2100 may be coupled to the system bus 2600 through a controller (not illustrated) or be directly coupled to the system bus 2600. When the memory device 2100 is directly coupled to the system bus 2600, functions of the controller may be performed by the CPU 2200 and the RAM 2300.

The memory device 2100 may be a non-volatile memory. The memory device 2100 may be the semiconductor memory strings described above with reference to FIGS. 1A to 18C. The memory device 2100 may include a first source layer including a trench, a second source layer formed in the trench, a structure including a plurality of conductive layers and a plurality of insulating layers formed alternately on the first and second source layers, and a plurality of channel layers passing through the structure and extending into the second source layer, in which the second source layer includes a base portion electrically connecting the channel layers adjacent to each other and a plurality of protruding portions protruding from the base portion, extending into the structure and partially surrounding the plurality of channel layers. Since the memory device 2100 is configured and manufactured in the same manner as the memory devices 1200 or 1200′, a detailed description thereof will be omitted.

In addition, as described above with reference to FIG. 20, the memory device 2100 may be a multi-chip package composed of a plurality of memory chips.

The computing system 2000 having the above-described configuration may be one of various components of an electronic device, such as a computer, an ultra-mobile PC (UMPC), a workstation, a net-book, personal digital assistants (PDAs), a portable computer, a web tablet, a wireless phone, a mobile phone, a smart phone, an e-book, a portable multimedia player (PMP), a portable game machine, a navigation device, a black box, a digital camera, a three-dimensional (3D) television, a digital audio recorder, a digital audio player, a digital picture recorder, a digital picture player, a digital video recorder, a digital video player, a device for transmitting/receiving information in wireless environments, one of various electronic devices for home networks, one of various electronic devices for computer networks, one of various electronic devices for telematics networks, an RFID device, and/or one of various devices for computing systems, etc.

As described above, since the computing system 2000 according to an embodiment includes the memory device 2100 having improved structural stability, simplified manufacturing processes, and increased degree of integration, stability and data storage capacity of the computing system 2000 may be improved.

FIG. 22 is a block diagram illustrating a computing system according to an embodiment.

As illustrated in FIG. 22, a computing system 3000 according to an embodiment may include a software layer that has an operating system 3200, an application 3100, a file system 3300, and a translation layer 3400. The computing system 3000 may include a hardware layer such as a memory system 3500.

The operating system 3200 may manage software and hardware resources of the computing system 3000. The operating system 3200 may control program execution of a central processing unit. The application 3100 may include various application programs executed by the computing system 3000. The application 3100 may be a utility executed by the operating system 3200.

The file system 3300 may refer to a logical structure configured to manage data and files present in the computing system 3000. The file system 3300 may organize files or data and store them in the memory device 3500 according to given rules. The file system 3300 may be determined depending on the operating system 3200 that is used in the computing system 3000. For example, when the operating system 3200 is a Microsoft Windows-based system, the file system 3300 may be a file allocation table (FAT) or an NT file system (NTFS). In addition, when the operating system 3200 is a Unix/Linux-based system, the file system 3300 may be an extended file system (EXT), a Unix file system (UFS) or a journaling file system (JFS).

FIG. 22 illustrates the operating system 3200, the application 3100, and the file system 3300 in separate blocks. However, the application 3100 and the file system 3300 may be included in the operating system 3200.

The translation layer 3400 may translate an address suitable for the memory device 3500 in response to a request from the file system 3300. For example, the translation layer 3400 may translate a logic address, which is generated by the file system 3300, into a physical address of the memory device 3500. Mapping information of the logic address and the physical address may be stored in an address translation table. For example, the translation layer 3400 may be a flash translation layer (FTL), a universal flash storage link layer (ULL), or the like.

The memory device 3500 may be a non-volatile memory and include the memory string described above with reference to FIGS. 1A to 18C. The memory device 3500 may include a first source layer including a trench, a second source layer formed in the trench, a structure including a plurality of conductive layers and a plurality of insulating layers formed alternately on the first and second source layers, and a plurality of channel layers passing through the structure and extending into the second source layer, in which the second source layer includes a base portion electrically connecting the channel layers adjacent to each other and a plurality of protruding portions protruding from the base portion, extending into the structure and partially surrounding the plurality of channel layers. Since the memory device 3500 is configured and manufactured in the same manner as the memory devices 1200, 1200′ or 2100, a detailed description thereof will be omitted.

The computing system 3000 having the above-described configuration may be divided into an operating system layer that is operated in an upper layer region and a controller layer that is operated in a lower level region. The application 3100, the operating system 3200, and the file system 3300 may be included in the operating system layer and driven by an operation memory. The translation layer 3400 may be included in the operating system layer or the controller layer.

As described above, since the computing system 3000 according to an embodiment includes the memory device 3500 capable of being manufactured by a simplified process and having improved characteristics, characteristics of the computing system 3000 may also be improved.

According to an embodiment, manufacturing processes may be easier to perform, and characteristics of an electronic device may be improved.

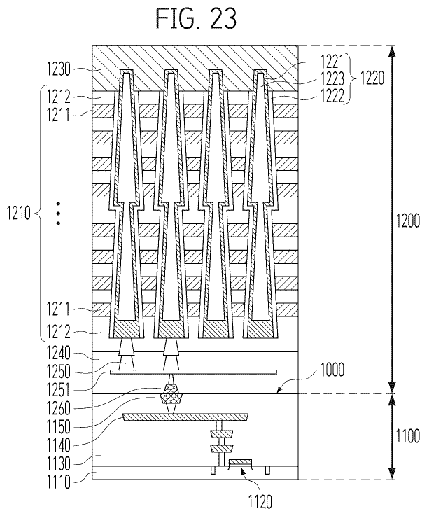

FIG. 23 is a diagram illustrating the structure of a semiconductor device in accordance with an embodiment.

Referring to FIG. 23, the semiconductor device may include a first semiconductor structure 1100 and a second semiconductor structure 1200. A bonding interface 1000 may be located in the semiconductor device, and the first semiconductor structure 1100 is distinguished from the second semiconductor structure 1200 by the bonding interface 1000. The second semiconductor structure 1200 may be disposed over or under the first semiconductor structure 1100. The first semiconductor structure 1100 may include a peripheral circuit, and the second semiconductor structure 1200 may include a memory cell array.

The first semiconductor structure 1100 may include a substrate 1110, a transistor 1120, a first interlayer insulating layer 1130, a first interconnection structure 1140, and a first bonding pad 1150. The transistor 1120 may be included in the peripheral circuit. The peripheral circuit may include a row decoder, a page buffer, an input/output circuit, a logic circuit, and the like. The first interconnection structure 1140 may be disposed in the first interlayer insulating layer 1130 and may include a via, a wiring line, and the like. The first bonding pad 1150 may be disposed at the bonding interface 1000 and may be electrically connected to the peripheral circuit through the first interconnection structure 1140.

The second semiconductor structure 1200 may include a gate structure 1210, a channel structure 1220, a source structure 1230, a second interlayer insulating layer 1240, a second interconnection structure 1250, and a second bonding pad 1260. The gate structure 1210 may include gate lines 1211 alternately stacked with insulating layers 1212. The source structure 1230 may be disposed over the gate structure 1210. The channel structure 1220 may include a channel layer 1221, a memory layer 1222, and/or an insulating core 1223. The channel layer 1221 may extend through the gate structure 1210 and may be connected to the source structure 1230. The second interconnection structure 1250 may be disposed in the second interlayer insulating layer 1240 and may include a via, a wiring line, and the like. For example, the second interconnection structure 1250 may include a bitline 1251. The second bonding pad 1260 may be disposed at the bonding interface 1000 and may be electrically connected to the memory cell array through the second interconnection structure 1250.

The first bonding pad 1150 may be electrically connected to the second bonding pad 1260 at the bonding interface 1000, and the memory cell array may be electrically connected to the peripheral circuit through the first bonding pad 1150 and the second bonding pad 1260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

Some of the first semiconductor structure 1100 and the second semiconductor structure 1200 may be formed after the first wafer is bonded to the second wafer. For example, the second wafer including a substrate, the gate structure 1210, and the channel structure 1220 may be formed, flipped, and bonded to the first wafer including the transistor 1120. Subsequently, a rear surface of the gate structure 1210 may be exposed by removing the substrate of the second wafer, and the channel layer 1221 may be exposed by etching the memory layer 1222 of the channel structure 1220 protruding from the rear surface of the gate structure 1210. The source structure 1230 may be formed on the rear surface of the gate structure 1210.

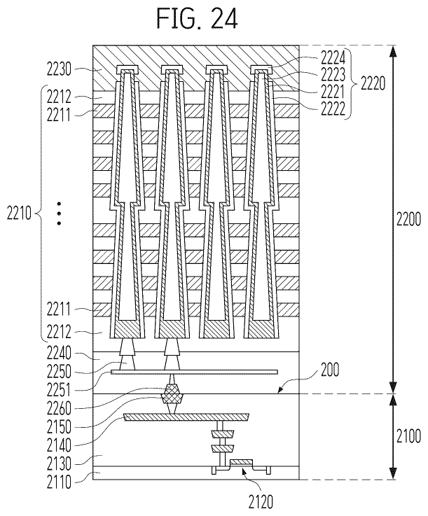

FIG. 24 is a diagram illustrating the structure of a semiconductor device in accordance with an embodiment.

Referring to FIG. 24, the semiconductor device may include a first semiconductor structure 2100 and a second semiconductor structure 2200. A bonding interface 2000 may be located in the semiconductor device, and the first semiconductor structure 2100 may be distinguished from the second semiconductor structure 2200 by the bonding interface 2000. The second semiconductor structure 2200 may be disposed over or under the first semiconductor structure 2100. The first semiconductor structure 2100 may include a peripheral circuit, and the second semiconductor structure 2200 may include a memory cell array.

The first semiconductor structure 2100 may include a substrate 2110, a transistor 2120, a first interlayer insulating layer 2130, a first interconnection structure 2140, and a first bonding pad 2150. The transistor 2120 may be included in the peripheral circuit. The peripheral circuit may include a row decoder, a page buffer, an input/output circuit, a logic circuit, and the like. The first interconnection structure 2140 may be disposed in the first interlayer insulating layer 2130 and may include a via, a wiring line, and the like. The first bonding pad 2150 may be disposed at the bonding interface 2000 and may be electrically connected to the peripheral circuit through the first interconnection structure 2140.

The second semiconductor structure 2200 may include a gate structure 2210, a channel structure 2220, a source structure 2230, a second interlayer insulating layer 2240, a second interconnection structure 2250, and a second bonding pad 2260. The gate structure 2210 may include gate lines 2211 alternately stacked with insulating layers 2212. The source structure 2230 may be disposed over the gate structure 2210. The channel structure 2220 may include a channel layer 2221, a memory layer 2222, an insulating core 2223, and/or a memory pattern 2224. The channel layer 2221 may extend through the gate structure 2210 and may be connected to the source structure 2230. The second interconnection structure 2250 may be disposed in the second interlayer insulating layer 2240 and may include a via, a wiring line, and the like. For example, the second interconnection structure 2250 may include a bitline 2251. The second bonding pad 2260 may be disposed at the bonding interface 2000 and may be electrically connected to the memory cell array through the second interconnection structure 2250.

The first bonding pad 2150 may be electrically connected to the second bonding pad 2260 at the bonding interface 2000, and the memory cell array may be electrically connected to the peripheral circuit through the first bonding pad 2150 and the second bonding pad 2260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

When the second wafer is manufactured, the source structure 2230 may be connected to the channel layer 2221 using a source sacrificial layer. For example, the channel structure 2220 may be formed to protrude into a source structure including the source sacrificial layer. An opening exposing the channel structure 2220 may be formed by removing the source sacrificial layer, and the channel layer 2221 may be exposed by etching the memory layer 2222 through the opening. A source layer connected to the channel layer 2221 may be formed in the opening to form the source structure 2230 including the source layer. The second wafer including the source structure 2230 may be flipped and bonded to the first wafer including the transistor 2120.

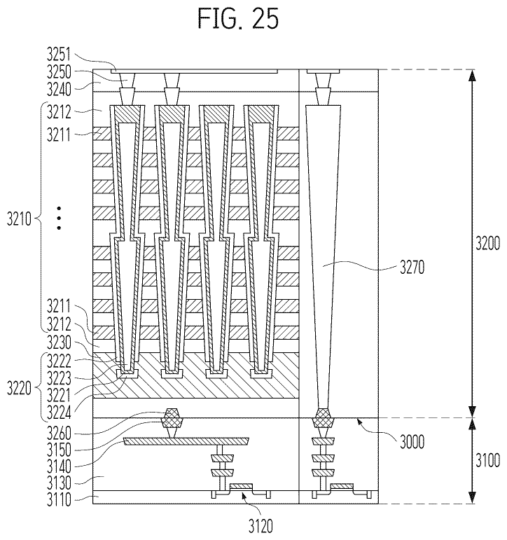

FIG. 25 is a diagram illustrating the structure of a semiconductor device in accordance with an embodiment.

Referring to FIG. 25, the semiconductor device may include a first semiconductor structure 3100 and a second semiconductor structure 3200. A bonding interface 3000 may be located in the semiconductor device, and the first semiconductor structure 3100 may be distinguished from the second semiconductor structure 3200 by the bonding interface 3000. The second semiconductor structure 3200 may be disposed over or under the first semiconductor structure 3100. The first semiconductor structure 3100 may include a peripheral circuit, and the second semiconductor structure 3200 may include a memory cell array.

The first semiconductor structure 3100 may include a substrate 3110, a transistor 3120, a first interlayer insulating layer 3130, a first interconnection structure 3140, and a first bonding pad 3150. The transistor 3120 may be included in the peripheral circuit. The peripheral circuit may include a row decoder, a page buffer, an input/output circuit, a logic circuit, and the like. The first interconnection structure 3140 may be disposed in the first interlayer insulating layer 3130 and may include a via, a wiring line, and the like. The first bonding pad 3150 may be disposed at the bonding interface 3000 and may be electrically connected to the peripheral circuit through the first interconnection structure 3140.

The second semiconductor structure 3200 may include a gate structure 3210, a channel structure 3220, a source structure 3230, a second interlayer insulating layer 3240, a second interconnection structure 3250, a second bonding pad 3260, and a contact plug 3270. The gate structure 3210 may include gate lines 3211 alternately stacked with insulating layers 3212. The source structure 3230 may be disposed below the gate structure 3210. The channel structure 3220 may include a channel layer 3221, a memory layer 3222, an insulating core 3223, and/or a memory pattern 3224. The channel layer 3221 may extend through the gate structure 3210, and may be connected to the source structure 3230. The second interconnection structure 3250 may be disposed in the second interlayer insulating layer 3240 and may include a via, a wiring line, and the like. For example, the second interconnection structure 3250 may include a bitline 3251. The second bonding pad 3260 may be disposed at the bonding interface 3000 and may be electrically connected to the memory cell array through the second interconnection structure 3250.

The first bonding pad 3150 may be electrically connected to the second bonding pad 3260 at the bonding interface 3000, and the memory cell array may be electrically connected to the peripheral circuit through the first bonding pad 3150 and the second bonding pad 3260. The contact plug 3270 may extend through the second interlayer insulating layer 3240 or a dummy stack and may be connected to the peripheral circuit through the first bonding pad 3150 and the second bonding pad 3260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

When the second wafer is manufactured, the source structure 3230 may be connected to the channel layer 3221 using a source sacrificial layer. For example, the channel structure 3220 protrudes into a source structure including the source sacrificial layer. Subsequently, an opening exposing the channel structure 3220 may be formed by removing the source sacrificial layer, and the channel layer 3221 may be exposed by etching the memory layer 3222 through the opening. A source layer connected to the channel layer 3221 may be formed in the opening to form the source structure 3230 including the source layer. The second wafer including the source structure 3230 may be bonded to the first wafer including the transistor 3120. In this example, the second wafer may be bonded to the first wafer in an un-flipped state. An interconnection structure such as a through silicon via (TSV) may be formed.

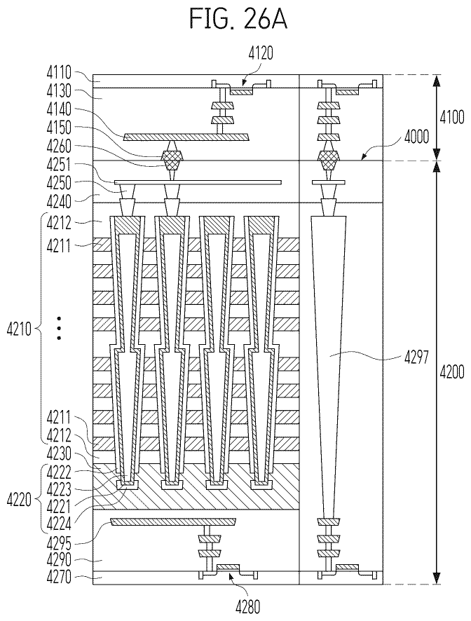

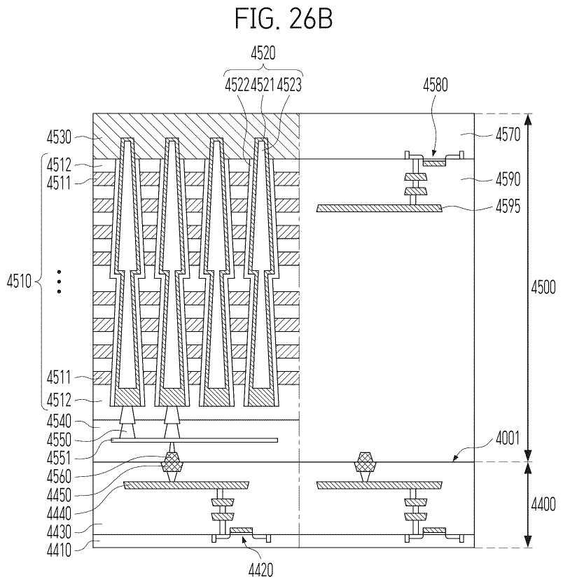

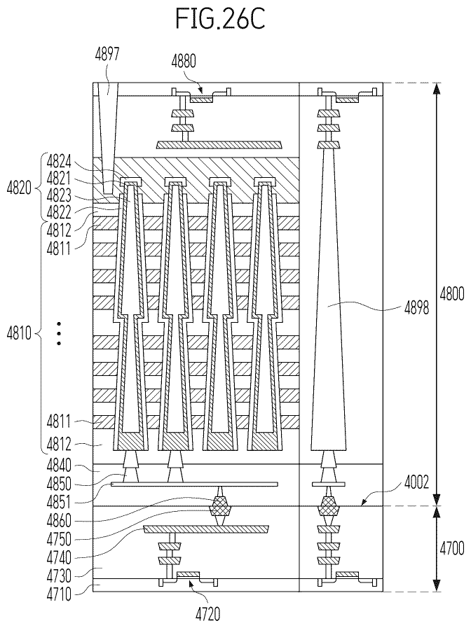

FIG. 26A is a diagram illustrating the structure of a semiconductor device in accordance with an embodiment.

Referring to FIG. 26A, the semiconductor device may include a first semiconductor structure 4100 and a second semiconductor structure 4200. A bonding interface 4000 may be located in the semiconductor device, and the first semiconductor structure 4100 may be distinguished from the second semiconductor structure 4200 by the bonding interface 4000. The second semiconductor structure 4200 may be disposed over or under the first semiconductor structure 4100. A peripheral circuit may include a first peripheral circuit and a second peripheral circuit. The first peripheral circuit and the second peripheral circuit may be distributed and disposed in the first semiconductor structure 4100 and the second semiconductor structure 4200. The first semiconductor structure 4100 may include the first peripheral circuit, and the second semiconductor structure 4200 may include the second peripheral circuit and a memory cell array.

The first semiconductor structure 4100 may include a first substrate 4110, a first transistor 4120, a first interlayer insulating layer 4130, a first interconnection structure 4140, and a first bonding pad 4150. The first transistor 4120 may be included in the first peripheral circuit. The first peripheral circuit may include a row decoder, a page buffer, an input/output circuit, a logic circuit, and the like. The first interconnection structure 4140 may be disposed in the first interlayer insulating layer 4130 and may include a via, a wiring line, and the like. The first bonding pad 4150 may be disposed at the bonding interface 4000 and may be electrically connected to the first peripheral circuit through the first interconnection structure 4140.

The second semiconductor structure 4200 may include a gate structure 4210, a channel structure 4220, a source structure 4230, a second interlayer insulating layer 4240, a second interconnection structure 4250, a second bonding pad 4260, a second substrate 4270, a second transistor 4280, a third interlayer insulating layer 4290, a third interconnection structure 4295, and a contact plug 4297.

The second transistor 4280 may be disposed on the second substrate 4270. The second transistor 4280 may be included in the second peripheral circuit. The second peripheral circuit may include a row decoder, a page buffer, an input/output circuit, a logic circuit, and the like. The third interconnection structure 4295 may be formed in the third interlayer insulating layer 4290 and may include a via, a wiring line, and the like. The third interconnection structure 4295 may be electrically connected to the second peripheral circuit.

The gate structure 4210 may be disposed over the second peripheral circuit. The gate structure 4210 may include gate lines 4211 alternately stacked with insulating layers 4212. The source structure 4230 may be disposed under the gate structure 4210. The channel structure 4220 may include a channel layer 4221, a memory layer 4222, an insulating core 4223, and/or a memory pattern 4224. The channel layer 4221 may extend through the gate structure 4210 and may be connected to the source structure 4230. The second interconnection structure 4250 may be disposed in the second interlayer insulating layer 4240 and may include a via, a wiring line, and the like. For example, the second interconnection structure 4250 may include a bitline 4251. The second bonding pad 4260 may be disposed at the bonding interface 4000 and may be electrically connected to the memory cell array through the second interconnection structure 4250.

The first bonding pad 4150 may be electrically connected to the second bonding pad 4260 at the bonding interface 4000, and the memory cell array may be electrically connected to the first peripheral circuit through the first bonding pad 4150 and the second bonding pad 4260. The contact plug 4297 may extend through the second interlayer insulating layer 4240 or a dummy stack. The first peripheral circuit may be connected to the second peripheral circuit through the contact plug 4297, the first bonding pad 4150 and the second bonding pad 4260.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

When the second wafer is manufactured, the source structure 4230 may be connected to the channel layer 4221 using a source sacrificial layer. For example, the second peripheral circuit may be formed on the second substrate 4270, and a source structure including the source sacrificial layer and the channel structure 4220 protruding into the source structure may be formed over the second peripheral circuit. An opening exposing the channel structure 4220 may be formed by removing the source sacrificial layer, and the channel layer 4221 may be exposed by etching the memory layer 4222 through the opening. A source layer connected to the channel layer 4221 may be formed in the opening to form the source structure 4230 including the source layer. The second wafer including the second peripheral circuit and the source structure 4230 may be bonded to the first wafer including the first peripheral circuit.

FIG. 26B is a diagram illustrating the structure of a semiconductor device in accordance with an embodiment.

Referring to FIG. 26B, the semiconductor device may include a first semiconductor structure 4400 and a second semiconductor structure 4500. A bonding interface 4001 may be located in the semiconductor device, and the first semiconductor structure 4400 may be distinguished from the second semiconductor structure 4500 by the bonding interface 4001. The second semiconductor structure 4500 may be disposed over or under the first semiconductor structure 4400. A peripheral circuit may include a first peripheral circuit and a second peripheral circuit. The first peripheral circuit and the second peripheral circuit may be distributed and disposed in the first semiconductor structure 4400 and the second semiconductor structure 4500. The first semiconductor structure 4400 may include the first peripheral circuit, and the second semiconductor structure 4500 may include the second peripheral circuit and a memory cell array.

The first semiconductor structure 4400 may include a first substrate 4410, a first transistor 4420, a first interlayer insulating layer 4430, a first interconnection structure 4440, and a first bonding pad 4450. The first transistor 4420 may be included in the first peripheral circuit. The first peripheral circuit may include a row decoder, a page buffer, an input/output circuit, a logic circuit, and the like. The first interconnection structure 4440 may be disposed in the first interlayer insulating layer 4430 and may include a via, a wiring line, and the like. The first interconnection structure 4440 may be electrically connected to the first peripheral circuit.

The second semiconductor structure 4500 may include a gate structure 4510, a channel structure 4520, a source structure 4530, a second interlayer insulating layer 4540, a second interconnection structure 4550, a second bonding pad 4560, a second substrate 4570, a second transistor 4580, a third interlayer insulating layer 4590, and a third interconnection structure 4595.

The second transistor 4580 may be disposed on the second substrate 4570. The second transistor 4580 may be included in the second peripheral circuit. The third interconnection structure 4595 may be formed in the third interlayer insulating layer 4590 and may include a via, a wiring line, and the like. The third interconnection structure 4595 may be electrically connected to the second peripheral circuit.

The source structure 4530 may be disposed at a level corresponding to the second substrate 4570, and the gate structure 4510 may be disposed under the source structure 4530. The gate structure 4510 may include gate lines 4511 alternately stacked with insulating layers 4512. The channel structure 4520 may include a channel layer 4521, a memory layer 4522, and/or an insulating core 4523. The channel layer 4521 may extend through the gate structure 4510 and may be connected to the source structure 4530. The second interconnection structure 4550 may be disposed in the second interlayer insulating layer 4540 and may include a via, a wiring line, and the like. For example, the second interconnection structure 4550 may include a bitline 4551. The second bonding pad 4560 may be disposed at the bonding interface 4001, and may be electrically connected to the memory cell array through the second interconnection structure 4550.

The first bonding pad 4450 may be electrically connected to the second bonding pad 4560 at the bonding interface 4001, and the memory cell array may be electrically connected to the first peripheral circuit through the first bonding pad 4450 and the second bonding pad 4560.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

Some of the first semiconductor structure 4400 and the second semiconductor structure 4500 may be formed after the first wafer is bonded to the second wafer. For example, the second peripheral circuit may be formed in a peripheral region of the second substrate 4560, and the channel structure 4520 protruding into the second substrate 4570 may be formed in a cell region of the second substrate 4570. The second wafer including the second peripheral circuit and the source structure 4530 may be flipped and bonded to the first wafer including the first peripheral circuit. Subsequently, a rear surface of the gate structure 4510 may be exposed by removing the cell region of the second substrate 4570, and the channel layer 4521 may be exposed by etching the memory layer 4522 of the channel structure 4520 protruding from the rear surface of the gate structure 4510. The source structure 4530 may be formed on the rear surface of the gate structure 4510.

FIG. 26C is a diagram illustrating the structure of a semiconductor device in accordance with an embodiment.

Referring to FIG. 26C, the semiconductor device may include a first semiconductor structure 4700 and a second semiconductor structure 4800. A bonding interface 4002 may be located in the semiconductor device, and the first semiconductor structure 4700 may be distinguished from the second semiconductor structure 4800 by the bonding interface 4002. The second semiconductor structure 4800 may be disposed over or under the first semiconductor structure 4700. A peripheral circuit may include a first peripheral circuit and a second peripheral circuit. The first peripheral circuit and the second peripheral circuit may be distributed and disposed in the first semiconductor structure 4700 and the second semiconductor structure 4800. The first semiconductor structure 4700 may include the first peripheral circuit, and the second semiconductor structure 4800 may include the second peripheral circuit and a memory cell array.

The first semiconductor structure 4700 may include a first substrate 4710, a first transistor 4720, a first interlayer insulating layer 4730, a first interconnection structure 4740, and a first bonding pad 4750. The first transistor 4720 may be included in the first peripheral circuit. The first peripheral circuit may include a row decoder, a page buffer, an input/output circuit, a logic circuit, and the like. The first interconnection structure 4740 may be disposed in the first interlayer insulating layer 4730 and may include a via, a wiring line, and the like. The first bonding pad 4750 may be disposed at the bonding interface 4002 and may be electrically connected to the first peripheral circuit through the first interconnection structure 4740.

The second semiconductor structure 4800 may include a gate structure 4810, a channel structure 4820, a source structure 4830, a second interlayer insulating layer 4840, a second interconnection structure 4850, a second bonding pad 4860, a second substrate 4870, a second transistor 4880, a third interlayer insulating layer 4890, a third interconnection structure 4895, a through via 4897, and a contact plug 4898.

The second transistor 4880 may be disposed on the second substrate 4870. The second transistor 4880 may be included in the second peripheral circuit. The second peripheral circuit may include a row decoder, a page buffer, an input/output circuit, a logic circuit, and the like. The third interconnection structure 4895 may be formed in the third interlayer insulating layer 4890 and may include a via, a wiring line, and the like. The third interconnection structure 4895 may be electrically connected to the second peripheral circuit.

The source structure 4830 may be disposed under the second peripheral circuit. The through via 4897 may extend through the second substrate 4870 and the third interlayer insulating layer 4890 and may be connected to the source structure 4830. The gate structure 4810 may be disposed under the source structure 4830. The gate structure 4810 may include gate lines 4811 alternately stacked with insulating layers 4812. The channel structure 4820 may include a channel layer 4821, a memory layer 4822, an insulating core 4823, and/or a memory pattern 4824. The channel layer 4821 may extend through the gate structure 4810 and may be connected to the source structure 4830. The second interconnection structure 4850 may be disposed in the second interlayer insulating layer 4840 and may include a via, a wiring line, and the like. For example, the second interconnection structure 4850 may include a bitline 4851. The second bonding pad 4860 may be disposed at the bonding interface 4002 and may be electrically connected to the memory cell array through the second interconnection structure 4850.

The first bonding pad 4750 may be electrically connected to the second bonding pad 4860 at the bonding interface 4002, and the memory cell array may be electrically connected to the first peripheral circuit through the first bonding pad 4750 and the second bonding pad 4860. The contact plug 4898 may extend through the second interlayer insulating layer 4840 or a dummy stack. The first peripheral circuit may be connected to the second peripheral circuit through the contact plug 4898, the first bonding pad 4750 and the second bonding pad 4860.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

Some of the first semiconductor structure 4700 and the second semiconductor structure 4800 may be formed after the first wafer may be bonded to the second wafer. For example, the second wafer including the second substrate 4870, the second peripheral circuit, and a source structure including a source sacrificial layer may be formed. The second wafer may be flipped and bonded to the first wafer including the first peripheral circuit. Subsequently, a through hole extending through the second substrate 4870 and the third interlayer insulating layer 4890 to expose the source sacrificial layer may be formed, and an opening, through which the channel structure 4820 is exposed, may be formed by removing the source sacrificial layer through the through hole. The channel layer 4821 may be exposed by etching the memory layer 4822 through the opening, and a source layer connected to the channel layer 4821 may be formed in the opening to form the source structure 4830 including the source layer. The through via 4897 may be formed in the through hole.

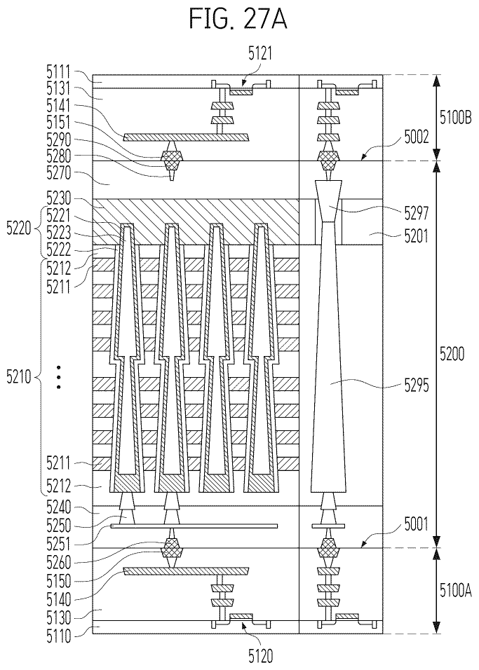

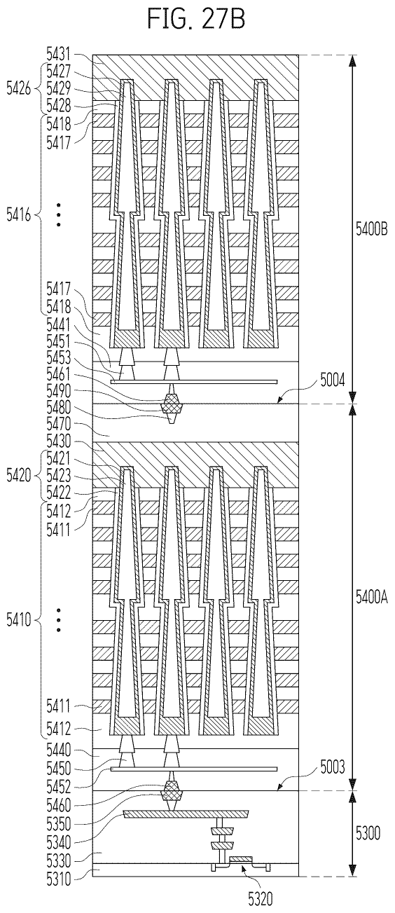

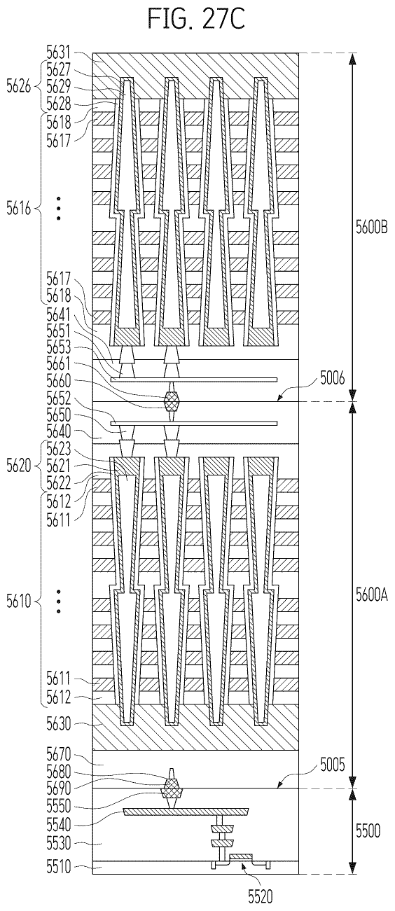

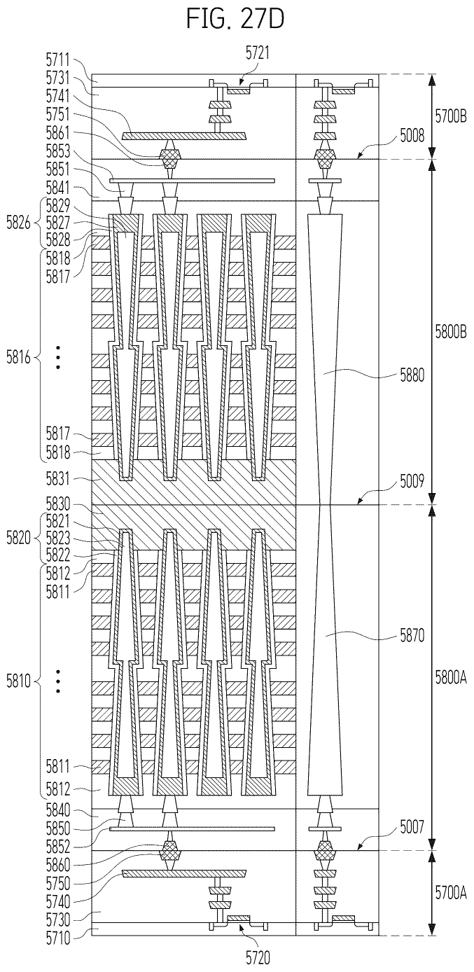

FIG. 27A is a diagram illustrating the structure of a semiconductor device in accordance with an embodiment.

Referring to FIG. 27A, the semiconductor device may include a first semiconductor structure 5100A, a second semiconductor structure 5100B, and a third semiconductor structure 5200. Bonding interfaces 5001 and 5002 may be located in the semiconductor device, and the first semiconductor structure 5100A, the second semiconductor structure 5100B, and the third semiconductor structure 5200 may be distinguished from each other by the bonding interfaces 5001 and 5002. The third semiconductor structure 5200 may be disposed between the first semiconductor structure 5100A and the second semiconductor structure 5100B. A peripheral circuit may include a first peripheral circuit and a second peripheral circuit. The first peripheral circuit and the second peripheral circuit may be distributed and disposed in the first semiconductor structure 5100A and the second semiconductor structure 5100B. The first semiconductor structure 5100A may include the first peripheral circuit, the second semiconductor structure 5100B may include the second peripheral circuit, and the third semiconductor structure 5200 may include a memory cell array.

The first semiconductor structure 5100A may include a first substrate 5110, a first transistor 5120, a first interlayer insulating layer 5130, a first interconnection structure 5140, and a first bonding pad 5150. The first transistor 5120 may be included in the first peripheral circuit. The first peripheral circuit may include a row decoder, a page buffer, an input/output circuit, a logic circuit, and the like. The first interconnection structure 5140 may be disposed in the first interlayer insulating layer 5130 and may include a via, a wiring line, and the like. The first bonding pad 5150 may be disposed at a first bonding interface 5001 and may be electrically connected to the first peripheral circuit through the first interconnection structure 5140.

The second semiconductor structure 5100B may include a second substrate 5111, a second transistor 5121, a second interlayer insulating layer 5131, a second interconnection structure 5141, and a second bonding pad 5151. The second transistor 5121 may be included in the second peripheral circuit. The second peripheral circuit may include a row decoder, a page buffer, an input/output circuit, a logic circuit, and the like. The second interconnection structure 5141 may be disposed in the second interlayer insulating layer 5131 and may include a via, a wiring line, and the like. The second bonding pad 5151 may be disposed at a second bonding interface 5002 and may be electrically connected to the second peripheral circuit through the second interconnection structure 5141.

The third semiconductor structure 5200 may include a substrate 5201, a gate structure 5210, a channel structure 5220, a source structure 5230, a third interlayer insulating layer 5240, a third interconnection structure 5250, a third bonding pad 5260, a fourth interlayer insulating layer 5270, a fourth interconnection structure 5280, a fourth bonding pad 5290, a first contact plug 5295, and a second contact plug 5297. The gate structure 5210 may include gate lines 5211 alternately stacked with insulating layers 5212. The source structure 5230 may be disposed over or under the gate structure 5210. The channel structure 5220 may include a channel layer 5221, a memory layer 5222, and/or an insulating core 5223. The channel layer 5221 may extend through the gate structure 5210 and may be connected to the source structure 5230. The third interconnection structure 5250 may be disposed in the third interlayer insulating layer 5240 and may include a via, a wiring line, and the like. For example, the third interconnection structure 5250 may include a bitline 5251. The fourth interconnection structure 5280 may be disposed in the fourth interlayer insulating layer 5270 and may include a via, a wiring line, and the like. The third bonding pad 5260 may be disposed at the first bonding interface 5001 and may be electrically connected to the memory cell array through the third interconnection structure 5250. The fourth bonding pad 5290 may be disposed at the second bonding interface 5002 and may be electrically connected to the memory cell array through the fourth interconnection structure 5280.

The first bonding pad 5150 may be electrically connected to the third bonding pad 5260 at the first bonding interface 5001, and the memory cell array may be electrically connected to the first peripheral circuit through the first bonding pad 5150 and the third bonding pad 5260. The second bonding pad 5151 may be electrically connected to the fourth bonding pad 5290 at the second bonding interface 5002, and the memory cell array may be electrically connected to the second peripheral circuit through the second bonding pad 5151 and the fourth bonding pad 5290.

The first contact plug 5295 may extend through the third interlayer insulating layer 5240 or a dummy stack, and the second contact plug 5297 may extend through the third substrate 5201. The first contact plug 5295 may be connected to the second contact plug 5297, and the first peripheral circuit may be connected to the second peripheral circuit through the first bonding pad 5150, the third bonding pad 5260, the first contact plug 5295, the second contact plug 5297, the fourth bonding pad 5290, and the second bonding pad 5151.

The semiconductor device may be manufactured using a method such as hybrid bonding, metal bonding, insulator bonding, or semiconductor bonding. The semiconductor device may be manufactured by manufacturing a first wafer including the first peripheral circuit, a second wafer including the second peripheral circuit, and a third wafer including the memory cell array, and bonding the first to third wafers together. For example, the third wafer may be flipped and bonded to the first wafer, and a substrate of the third wafer may be removed to form the source structure 5230. The second wafer may be flipped and bonded to the third wafer.

FIG. 27B is a diagram illustrating the structure of a semiconductor device in accordance with an embodiment.

Referring to FIG. 27B, the semiconductor device may include a first semiconductor structure 5300, a second semiconductor structure 5400A, and a third semiconductor structure 5400B. Bonding interfaces 5003 and 5004 may be located in the semiconductor device, and the first semiconductor structure 5300, the second semiconductor structure 5400A, and the third semiconductor structure 5400B may be distinguished by the bonding interfaces 5003 and 5004. The second semiconductor structure 5400A may be disposed between the first semiconductor structure 5300 and the third semiconductor structure 5400B. The first semiconductor structure 5300 may include a peripheral circuit, the second semiconductor structure 5400A may include a first memory cell array, and the third semiconductor structure 5400B may include a second memory cell array.

The first semiconductor structure 5300 may include a substrate 5310, a transistor 5320, a first interlayer insulating layer 5330, a first interconnection structure 5340, and a first bonding pad 5350. The transistor 5320 may be included in the peripheral circuit. The peripheral circuit may include a row decoder, a page buffer, an input/output circuit, a logic circuit, and the like. The first interconnection structure 5340 may be disposed in the first interlayer insulating layer 5330 and may include a via, a wiring line, and the like. The first bonding pad 5350 may be disposed at a first bonding interface 5003 and may be electrically connected to the peripheral circuit through the first interconnection structure 5340.

The second semiconductor structure 5400A may include a first gate structure 5410, a first channel structure 5420, a first source structure 5430, a second interlayer insulating layer 5440, a second interconnection structure 5450, a second bonding pad 5460, a third interlayer insulating layer 5470, a third interconnection structure 5480, and a third bonding pad 5490. The first gate structure 5410 may include first gate lines 5411 alternately stacked with first insulating layers 5412. The first source structure 5430 may be disposed over or under the first gate structure 5410. The first channel structure 5420 may include a first channel layer 5421, a first memory layer 5422, and/or a first insulating core 5423. The first channel layer 5421 may extend through the first gate structure 5410 and may be connected to the first source structure 5430. The second interconnection structure 5450 may be disposed in the second interlayer insulating layer 5440 and may include a via, a wiring line, and the like. For example, the second interconnection structure 5450 may include a bitline 5452. The third interconnection structure 5480 may be disposed in the third interlayer insulating layer 5470 and may include a via, a wiring line, and the like. The second bonding pad 5460 may be disposed at the first bonding interface 5003 and may be electrically connected to the first memory cell array through the second interconnection structure 5450. The third bonding pad 5490 may be disposed at a second bonding interface 5004, and may be electrically connected to the first memory cell array through the third interconnection structure 5480.

The third semiconductor structure 5400B may include a second gate structure 5416, a second channel structure 5426, a second source structure 5431, a fourth interlayer insulating layer 5441, a fourth interconnection structure 5451, and a fourth bonding pad 5461. The second gate structure 5416 may include second gate lines 5417 alternately stacked with second insulating layer 5418. The second source structure 5431 may be disposed over or under the second gate structure 5416. The second source structure 5431 may be electrically isolated from the first source structure 5430 and driven separately from the first source structure 5430 or may be electrically connected to the first source structure 5430 and driven in common with the first source structure 5430. The second channel structure 5426 may include a second channel layer 5427, a second memory layer 5428, and/or a second insulating core 5429. The second channel layer 5427 may extend through the second gate structure 5416 and may be connected to the second source structure 5431. The fourth interconnection structure 5451 may be disposed in the fourth interlayer insulating layer 5441 and may include a via, a wiring line, and the like. For example, the fourth interconnection structure 5451 may include a bitline 5453. The fourth bonding pad 5461 may be disposed at the second bonding interface 5004 and may be electrically connected to the second memory cell array through the fourth interconnection structure 5451.

The first bonding pad 5350 may be electrically connected to the second bonding pad 5460 at the first bonding interface 5003, and the first memory cell array may be electrically connected to the peripheral circuit through the first bonding pad 5350 and the second bonding pad 5460. The third bonding pad 5490 may be electrically connected to the fourth bonding pad 5461 at the second bonding interface 5004, and the second memory cell array may be electrically connected to the first memory cell array through the third bonding pad 5490 and the fourth bonding pad 5461.

The semiconductor device may be manufactured using a method such as hybrid bonding, metal bonding, insulator bonding, or semiconductor bonding. The semiconductor device may be manufactured by manufacturing a first wafer including the peripheral circuit, a second wafer including the first memory cell array, and a third wafer including the second memory cell array, and bonding the first to third wafers together. For example, the second wafer may be flipped and bonded to the first wafer, and a substrate of the second wafer may be removed to form the first source structure 5430. The third wafer may be flipped and bonded to the second wafer, and a substrate of the third wafer may be removed to form the second source structure 5431.

FIG. 27C is a diagram illustrating the structure of a semiconductor device in accordance with an embodiment.

Referring to FIG. 27C, the semiconductor device may include a first semiconductor structure 5500, a second semiconductor structure 5600A, and a third semiconductor structure 5600B. Bonding interfaces 5005 and 5006 may be located in the semiconductor device, and the first semiconductor structure 5500, the second semiconductor structure 5600A, and the third semiconductor structure 5600B may be distinguished by the bonding interfaces 5005 and 5006. The second semiconductor structure 5600A may be disposed between the first semiconductor structure 5500 and the third semiconductor structure 5600B. The first semiconductor structure 5500 may include a peripheral circuit, the second semiconductor structure 5600A may include a first memory cell array, and the third semiconductor structure 5600B may include a second memory cell array.

The first semiconductor structure 5500 may include a substrate 5510, a transistor 5520, a first interlayer insulating layer 5530, a first interconnection structure 5540, and a first bonding pad 5550. The transistor 5520 may be included in the peripheral circuit. The peripheral circuit may include a row decoder, a page buffer, an input/output circuit, a logic circuit, and the like. The first interconnection structure 5540 may be disposed in the first interlayer insulating layer 5530 and may include a via, a wiring line, and the like. The first bonding pad 5550 may be disposed at a first bonding interface 5005 and may be electrically connected to the peripheral circuit through the first interconnection structure 5540.

The second semiconductor structure 5600A may include a first gate structure 5610, a first channel structure 5620, a first source structure 5630, a second interlayer insulating layer 5640, a second interconnection structure 5650, a second bonding pad 5660, a third interlayer insulating layer 5670, a third interconnection structure 5680, and a third bonding pad 5690. The first gate structure 5610 may include first gate lines 5611 alternately stacked with first insulating layers 5612. The first source structure 5630 may be disposed over or under the first gate structure 5610. The first channel structure 5620 may include a first channel layer 5621, a first memory layer 5622, and/or a first insulating core 5623. The first channel layer 5621 may extend through the first gate structure 5610 and may be connected to the first source structure 5630. The second interconnection structure 5650 may be disposed in the second interlayer insulating layer 5640 and may include a via, a wiring line, and the like. For example, the second interconnection structure 5650 may include a bitline 5652. The third interconnection structure 5680 may be disposed in the third interlayer insulating layer 5670 and may include a via, a wiring line, and the like. The second bonding pad 5660 may be disposed at a second bonding interface 5006 and may be electrically connected to the first memory cell array through the second interconnection structure 5650. The third bonding pad 5690 may be disposed at the first bonding interface 5005 and may be electrically connected to the first memory cell array through the third interconnection structure 5680.

The third semiconductor structure 5600B may include a second gate structure 5616, a second channel structure 5626, a second source structure 5631, a fourth interlayer insulating layer 5641, a fourth interconnection structure 5651, and a fourth bonding pad 5661. The second gate structure 5616 may include second gate lines 5617 alternately stacked with second insulating layer 5618. The second source structure 5631 may be disposed over or under the second gate structure 5616. The second source structure 5631 may be electrically isolated from the first source structure 5630 and driven separately from the first source structure 5630 or may be electrically connected to the first source structure 5630 and driven in common with the first source structure 5630. The second channel structure 5626 may include a second channel layer 5627, a second memory layer 5628, and/or a second insulating core 5629. The second channel layer 5627 may extend through the second gate structure 5616 and may be connected to the second source structure 5631. The fourth interconnection structure 5651 may be disposed in the fourth interlayer insulating layer 5641 and may include a via, a wiring line, and the like. For example, the fourth interconnection structure 5651 may include a bitline 5653. The fourth bonding pad 5661 may be disposed at the second bonding interface 5006 and may be electrically connected to the second memory cell array through the fourth interconnection structure 5651.

The first bonding pad 5550 may be electrically connected to the third bonding pad 5690 at the first bonding interface 5005, and the first memory cell array may be electrically connected to the peripheral circuit through the first bonding pad 5550 and the third bonding pad 5690. The second bonding pad 5660 may be electrically connected to the fourth bonding pad 5661 at the second bonding interface 5006, and the second memory cell array may be electrically connected to the first memory cell array through the second bonding pad 5660 and the fourth bonding pad 5661.

The semiconductor device may be manufactured using a method such as hybrid bonding, metal bonding, insulator bonding, or semiconductor bonding. The semiconductor device may be manufactured by manufacturing a first wafer including the peripheral circuit, a second wafer including the first memory cell array, and a third wafer including the second memory cell array, and bonding the first to third wafers together. For example, the second wafer may be flipped and bonded to the third wafer, and a substrate of the second wafer may be removed to form the first source structure 5630. The second wafer and the first wafer may be bonded, and a substrate of the third wafer may be removed to form the second source structure 5631.

FIG. 27D is a diagram illustrating the structure of a semiconductor device in accordance with an embodiment.

Referring to FIG. 27D, the semiconductor device may include a first semiconductor structure 5700A, a second semiconductor structure 5700B, a third semiconductor structure 5800A, and a fourth semiconductor structure 5800B. Bonding interfaces 5007, 5008, and 5009 may be located in the semiconductor device, and the first semiconductor structure 5700A, the second semiconductor structure 5700B, the third semiconductor structure 5800A, and the fourth semiconductor structure 5800B may be distinguished by the bonding interfaces 5007, 5008, and 5009. The third semiconductor structure 5800A and the fourth semiconductor structure 5800B may be disposed between the first semiconductor structure 5700A and the second semiconductor structure 5700B. The first semiconductor structure 5700A may include a first peripheral circuit, the second semiconductor structure 5700B may include a second peripheral circuit, the third semiconductor structure 5800A may include a first memory cell array, and the fourth semiconductor structure 5800B may include a second memory cell array.

The first semiconductor structure 5700A may include a first substrate 5710, a first transistor 5720, a first interlayer insulating layer 5730, a first interconnection structure 5740, and a first bonding pad 5750. The first transistor 5720 may be included in the first peripheral circuit. The first peripheral circuit may include a row decoder, a page buffer, an input/output circuit, a logic circuit, and the like. The first interconnection structure 5740 may be disposed in the first interlayer insulating layer 5730 and may include a via, a wiring line, and the like. The first bonding pad 5750 may be disposed at a first bonding interface 5007 and may be electrically connected to the first peripheral circuit through the first interconnection structure 5740.

The second semiconductor structure 5700B may include a second substrate 5711, a second transistor 5721, a second interlayer insulating layer 5731, a second interconnection structure 5741, and a second bonding pad 5751. The second transistor 5721 may be included in the second peripheral circuit. The second peripheral circuit may include a row decoder, a page buffer, an input/output circuit, a logic circuit, and the like. The second interconnection structure 5741 may be disposed in the second interlayer insulating layer 5731 and may include a via, a wiring line, and the like. The second bonding pad 5751 may be disposed at a second bonding interface 5008 and may be electrically connected to the second peripheral circuit through the second interconnection structure 5741.

The third semiconductor structure 5800A may include a first gate structure 5810, a first channel structure 5820, a first source structure 5830, a third interlayer insulating layer 5840, a third interconnection structure 5850, a third bonding pad 5860, and a first contact plug 5870. The first gate structure 5810 may include first gate lines 5811 alternately stacked with first insulating layers 5812. The first source structure 5830 may be disposed over or under the first gate structure 5810. The first channel structure 5820 may include a first channel layer 5821, a first memory layer 5822, and/or a first insulating core 5823. The first channel layer 5821 may extend through the first gate structure 5810 and may be connected to the first source structure 5830. The third interconnection structure 5850 may be disposed in the third interlayer insulating layer 5840 and may include a via, a wiring line, and the like. For example, the third interconnection structure 5850 may include a bitline 5852. The third bonding pad 5860 may be disposed at the first bonding interface 5007 and may be electrically connected to the first memory cell array through the third interconnection structure 5850.

The fourth semiconductor structure 5800B may include a second gate structure 5816, a second channel structure 5826, a second source structure 5831, a fourth interlayer insulating layer 5841, a fourth interconnection structure 5851, a fourth bonding pad 5861, and a second contact plug 5880. The second gate structure 5816 may include second gate lines 5817 alternately stacked with second insulating layer 5818. The second source structure 5831 may be disposed over or under the second gate structure 5816. The second source structure 5831 may be electrically connected to the first source structure 5830 and driven in common with the first source structure 5830. The second channel structure 5826 may include a second channel layer 5827, a second memory layer 5828, and/or a second insulating core 5829. The second channel layer 5827 may extend through the second gate structure 5816 and may be connected to the second source structure 5831. The fourth interconnection structure 5851 may be disposed in the fourth interlayer insulating layer 5841 and may include a via, a wiring line, and the like. For example, the fourth interconnection structure 5851 may include a bitline 5853. The fourth bonding pad 5861 may be disposed at the second bonding interface 5008 and may be electrically connected to the second memory cell array through the fourth interconnection structure 5851.

The first bonding pad 5750 may be electrically connected to the third bonding pad 5860 at the first bonding interface 5007, and the first memory cell array may be electrically connected to the first peripheral circuit through the first bonding pad 5750 and the third bonding pad 5860. The second bonding pad 5751 may be electrically connected to the fourth bonding pad 5861 at the second bonding interface 5008, and the second memory cell array may be electrically connected to the second peripheral circuit through the second bonding pad 5751 and the fourth bonding pad 5861. The first source structure 5830 may be bonded to the second source structure 5831 at a third bonding interface 5009. Thus, the first memory cell array may be electrically connected to the second memory cell array.

The first contact plug 5870 may extend through the third interlayer insulating layer 5840 or a dummy stack, and the second contact plug 5880 may extend through the fourth interlayer insulating layer 5841 or a dummy stack. The first contact plug 5870 may be connected to the second contact plug 5880, and the first peripheral circuit may be connected to the second peripheral circuit through the first bonding pad 5750, the third bonding pad 5860, the first contact plug 5870, the second contact plug 5880, the fourth bonding pad 5861, and the second bonding pad 5751.

The semiconductor device may be manufactured using a method such as hybrid bonding, metal bonding, insulator bonding, or semiconductor bonding. The semiconductor device may be manufactured by manufacturing a first wafer including the first peripheral circuit, a second wafer including the first memory cell array, a third wafer including the second peripheral circuit, and a fourth wafer including the second memory cell array, and bonding the first to fourth wafers together. For example, the second wafer may be flipped and bonded to the first wafer, and a substrate of the second wafer may be removed to form the first source structure 5830. The fourth wafer may be flipped and bonded to the third wafer, and a substrate of the fourth wafer may be removed to form the second source structure 5831. The second wafer may be bonded to the fourth wafer.

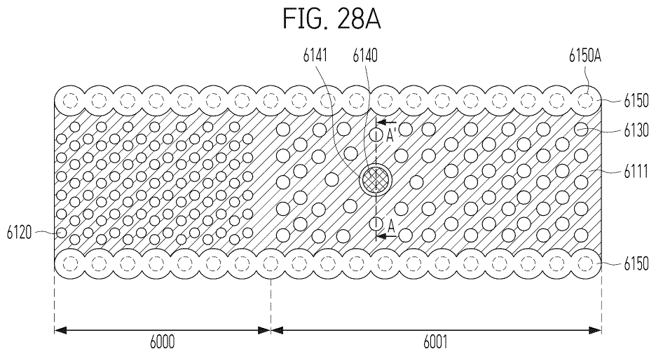

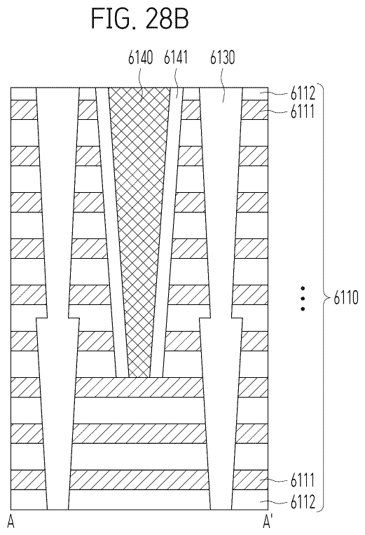

FIGS. 28A and 28B are diagrams illustrating the structure of a semiconductor device in accordance with an embodiment. FIG. 28B is a cross-sectional view taken along line A-A′ of FIG. 28A.

Referring to FIGS. 28A and 28B, the semiconductor device may include a gate structure 6110, channel structures 6120, supports 6130, a contact plug 6140, an insulating spacer 6141, and slit structures 6150. The term “slit structure” in the present disclosure does not indicate that a slit has a structure but rather is so named because the process of forming a slit structure utilizes a slit. The slit structures 6150 may extend in one direction, and the gate structure 6110 may be disposed between the slit structures 6150. Each of the slit structures 6150 may include an insulating material, a semiconductor material, and/or a conductive material. The gate structure 6110 may include gate lines 6111 alternately stacked with insulating layers 6112. The gate lines may be word lines, a source select line, or a drain select line.

The gate structure 6110 may include a cell region 6000 and a contact region 6001. The channel structures 6120 may be disposed in the cell region 6000 of the gate structure 6110. The channel structures 6120 may extend in a vertical direction through the gate structure 6110, and memory cells may be stacked along the channel structures 6120. The supports 6130 and the contact plug 6140 may be disposed in the contact region 6001 of the gate structure 6110. The supports 6130 may extend in the vertical direction through the gate structure 6110. Each of the supports 6130 may include an insulating material, a semiconductor material, and/or a conductive material.

The contact plug 6140 may be electrically connected to a gate line 6111. For example, the contact region 6001 of the gate structure 6110 may include a staircase structure (not shown), and the contact plug 6140 may be electrically connected to the gate line through the staircase structure. For example, the gate structure 6110 may not include the staircase structure, and the contact plug 6140 may extend through the gate structure 6110 and be electrically connected to the gate line. The insulating spacer 6141 may surround a sidewall of the contact plug 6140.

Processes of manufacturing the channel structures 6120, the supports 6130, and the slit structures 6150 may be performed simultaneously. Holes that form the channel structures 6120, the supports 6130, and the slit structures 6150 may be simultaneously formed, and sacrificial layers may be formed in the holes. The sacrificial layers are removed to form holes, and structures are formed within the holes. For example, holes 6150A arranged in a row may be formed in a region where the slit structure is to be formed. A slit may be formed by expanding the holes 6150A thereby connecting the holes 6150A together, and the slit structure 6150 may be formed in the slit. In such an example, the sidewalls of the slit structure 6150 may include irregularities or uneven surfaces.

The semiconductor device may be manufactured using a replacement process. For example, a stack may be formed including sacrificial layers alternately stacked with insulating layers, and a contact hole may be formed extending through the stack. A sacrificial pattern may be formed in the contact hole, and the sacrificial layers may be replaced with the gate lines 6111 to form the gate structure 6110. The sacrificial pattern may be removed, and the insulating spacer 6141 may be formed on sidewalls of the stack exposed by the contact hole. The contact plug 6140 may be formed within the insulating spacer 6141 formed in the contact hole.

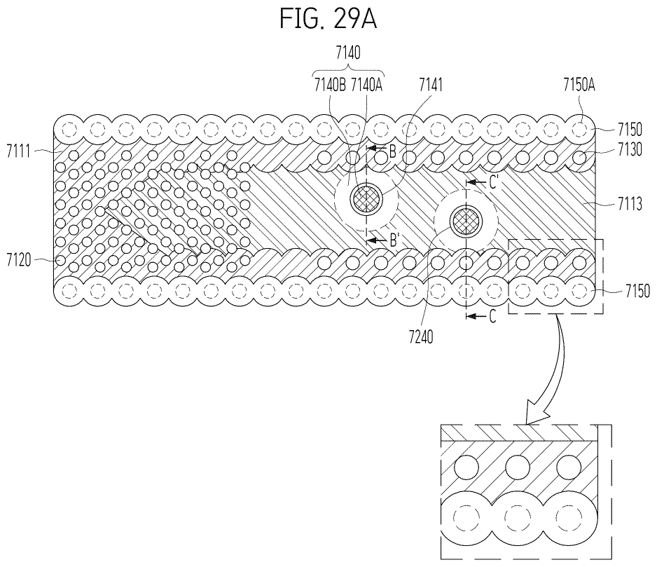

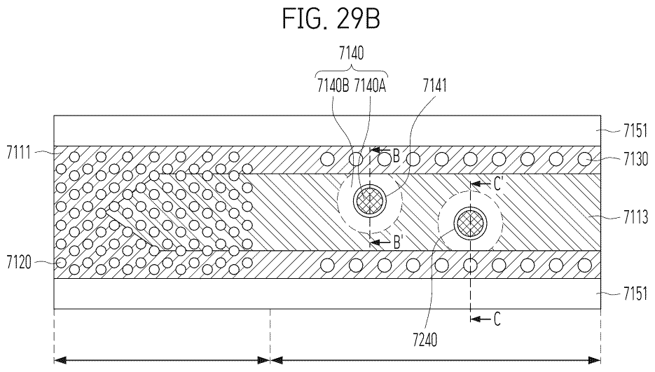

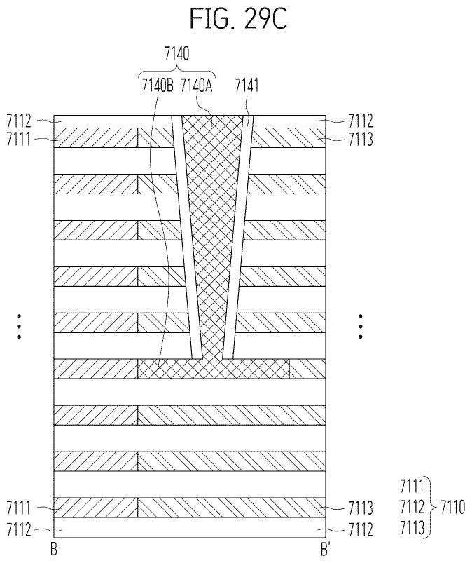

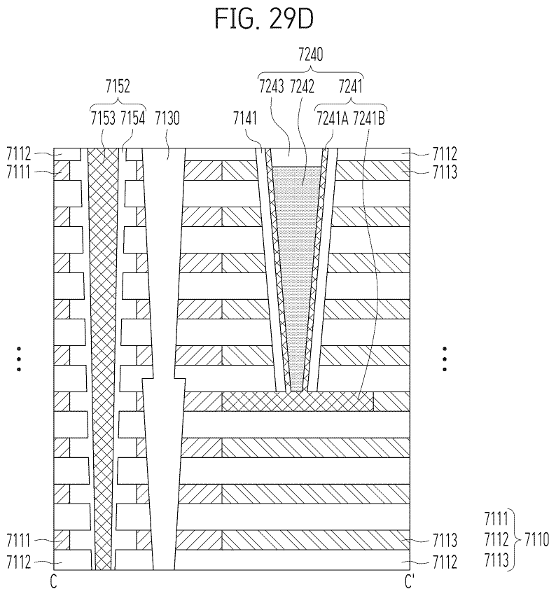

FIGS. 29A to 29D are a diagram illustrating the structure of a semiconductor device in accordance with an embodiment. FIG. 29C is a cross-sectional view taken along line B-B′ of FIG. 29A. FIG. 29D is a modified example of FIG. 29C and is a cross-sectional view taken along line C-C′ of FIG. 29A.

Referring to FIGS. 29A and 29B, the semiconductor device may include a gate structure 7110, channel structures 7120, supports 7130, a contact plug 7140, an insulating spacer 7141, and slit structures 7150 and 7151.

The slit structures 7150 may extend in one direction, and the gate structure 7110 may be disposed between the slit structures 7150. Referring to FIG. 29A, the slit structures 7150 may be formed within a slit defined by extending and connecting holes 7150A arranged in a row, and may have irregularities on their sidewalls. Referring to FIG. 29B, the slit structure 7151 may be formed within a line-shaped slit, and the sidewalls may have a linear shape without irregularities. Each of the slit structures 7150 and 7151 may include an insulating material, a semiconductor material, and/or a conductive material.

The gate structure 7110 may include gate lines 7111, insulating layers 7112, and dielectric layers 7113. The gate lines 7111 are alternately stacked with the insulating layers 7112, and the insulating layers 7112 may extend between the stacked dielectric layers 7113. The gate line 7111 may surround the dielectric layer 7113. The interface between the gate line 7111 and the dielectric layer 7113 may be uneven or corrugated, or may have a linear shape. The supports 7130 may be disposed between the dielectric layers 7113 and the slit structures 7150, and may extend through the gate lines 7111 and the insulating layers 7112.

The contact plug 7140 may include a pillar portion 7140A and a contact portion 7140B protruding from the pillar portion 7140A. The pillar portion 7140A and the contact portion 7140B may be formed as a single layer or may be formed as separate layers. The pillar portion 7140A may extend in the vertical direction through the insulating layers 7112 and the dielectric layers 7113. The contact portion 7140B may be disposed at a level corresponding to a dielectric layer 7113 and may extend in a horizontal direction to be electrically connected to the gate line 7111. The insulating spacer 7141 may surround the pillar portion 7140A. The semiconductor device may include a plurality of contact plugs 7140, and each of the plurality of contact plugs 7140 may extend to a different depth and be connected to a different gate line 7111. In an embodiment, the pillar 7120A and the contact 7120B are formed as a single unified structure, for example, formed in one process using the same material. Alternatively, the pillar 7120A and the contact 7120B may be formed separately and connected together.

Referring to FIGS. 29A and 29D, the semiconductor device may include a gate structure 7110, channel structures 7120, a contact plug 7240, an insulating spacer 7141, supports 7130, and a slit structure 7152. The gate structure 7110 may include gate lines 7111, insulating layers 7112, and dielectric layers 7113. The gate lines 7111 are alternately stacked with the insulating layers 7112, and the insulating layers 7112 may extend between the stacked dielectric layers 7113.

The supports 7130 may extend through the gate lines 7111 that are alternately stacked with the insulating layers 7112. The supports 7130 may each include an insulating material, a semiconductor material, and/or a conductive material. The slit structure 7152 may include a structure formed in a slit used as a passage for a replacement process and may extend between adjacent gate structures 7110. For example, the slit structure 7152 may include a conductive layer 7153 and an insulating spacer 7154 surrounding sidewalls of the conductive layer 7153. The insulating spacer 7154 may include protrusions protruding toward the gate lines 7111.

The contact plug 7240 may include a barrier layer 7241, a gap-fill insulating layer 7242, and a contact pad 7243. The gap-fill insulating layer 7242 may extend in the vertical direction through the dielectric layers 7113 and the insulating layers 7112. The contact pad 7243 may be disposed over the gap-fill insulating layer 7242 and may include metal such as tungsten. The barrier layer 7241 may include a pillar portion 7241A and a contact portion 7241B. The pillar portion 7241A may surround sidewalls of the gap-fill insulating layer 7242 and the contact pad 7243. The contact portion 7241B may be disposed below a lower surface of the gap-fill insulating layer 7242 and may extend in the horizontal direction to electrically connect to the gate line 7111. The insulating spacer 7141 may surround the pillar portion 7241A. The semiconductor device may include a plurality of contact plugs 7240, and each of the plurality of contact plugs 7240 may extend to a different depth and is connected to a different gate line 7111.

The semiconductor device may be manufactured using a replacement process. For example, the gate structure 7110 may be formed by forming a stack including sacrificial layers alternately stacked with the insulating layers 7112 and replacing the sacrificial layers with the gate lines 7111 through the slit. The stack may include a cell region and a contact region, and the sacrificial layers may remain in a region of the contact region spaced apart from the slit. The dielectric layers 7113 of the gate structure 7110 may be the remaining sacrificial layers. A contact hole extending through the insulating layers 7112 and the dielectric layers 7113 may be formed, and the insulating spacer 7141 may be formed on sidewalls of the stack exposed by the contact hole. By etching the dielectric layer 7113 exposed at a lower end of the insulating spacer 7141 and the contact hole, a lower end of the contact hole may be expanded in the horizontal direction to expose the gate line 7111. The contact plug 7140 or the contact plug 7240 may be formed within the insulating spacer 7141 formed in the contact hole.

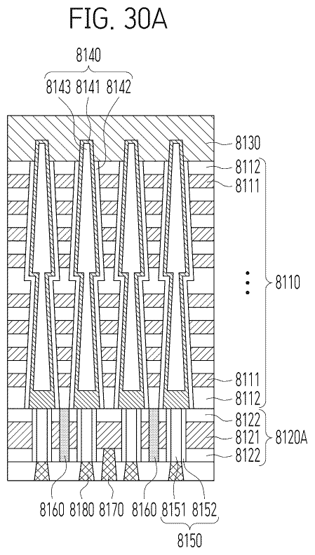

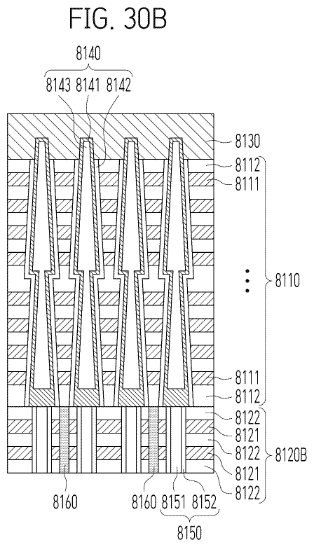

FIGS. 30A and 30B are diagrams illustrating the structure of a semiconductor device in accordance with an embodiment.

Referring to FIGS. 30A and 30B, the semiconductor device may include a first gate structure 8110, a second gate structure 8120A or 8120B, a source structure 8130, a first channel structure 8140, a second channel structure 8150, and an isolation insulating structure 8160. The first gate structure 8110 may include first gate lines 8111 alternately stacked with first insulating layers 8112. The first gate lines 8111 may be word lines or a source select line. The source structure 8130 may be disposed over the first gate structure 8110.

The second gate structure 8120A or 8120B may be disposed under the first gate structure 8110. Referring to FIG. 30A, the second gate structure 8120A may include a second gate line 8121 alternately stacked with second insulating layers 8122. The first contact plug 8170 may be connected to the second gate line 8121, and the second contact plugs 8180 may be connected to the second channel structures 8150. The first contact plug 8170 and the second contact plugs 8180 may be located in a cell region. Referring to FIG. 30B, the second gate structure 8120B may include second gate lines 8121 alternately stacked with second insulating layers 8122. Contact plugs may be connected to respective ones of the second gate lines 8121, and the contact plugs may be located in a contact region.

The second gate line 8121 may be a drain select line. The second gate line 8121 may be thicker than the first gate line 8111 or have substantially the same thickness as the first gate line 8111. The second gate line 8121 may include a different material from the first gate line 8111. For example, the first gate line 8111 may include metal such as tungsten (W) or molybdenum (Mo), and the second gate line 8121 may include polysilicon. Consecutive second gate lines 8121 disposed at the same level may be insulated by an isolation insulating structure 8160. In a plan view, the isolation insulating structures 8160 may extend in a line or a wave or zigzag shape.

The first channel structures 8140 may extend through the first gate structure 8110. The first channel structure 8140 may include a first channel layer 8141, a memory layer 8142, and/or an insulating core 8143. The second channel structures 8150 may extend through the second gate structure 8120A or 8120B and may be connected to the first channel structures 8140. The second channel structure 8150 may include a second channel layer 8151 and a gate insulating layer 8152.

The first gate structure 8110 and the second gate structure 8120A or 8120B may be formed by separate processes. For example, the first gate structure 8110 may be formed by forming a stack including sacrificial layers alternately stacked with the first insulating layers 8112 and replacing the sacrificial layers with the first gate lines 8111. The second gate structure 8120A or 8120B may be formed on the first gate structure 8110. At least one conductive layer and the second insulating layers 8122 may be formed, and the second gate lines 8121 and trenches between the second gate lines 8121 may be formed by etching at least one conductive layer and the second insulating layers 8122. The isolation insulating structures 8160 may be formed in the trenches.

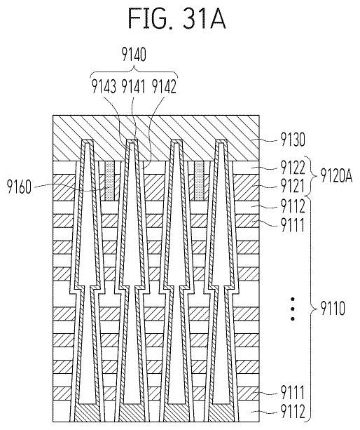

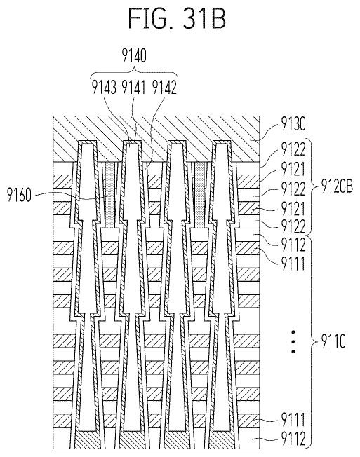

FIGS. 31A and 31B are diagrams illustrating the structure of a semiconductor device in accordance with an embodiment.

Referring to FIGS. 31A and 31B, a semiconductor device may include a first gate structure 9110, a second gate structure 9120A or 9120B, a source structure 9130, a channel structure 9140, and an isolation insulating structure 9160. The first gate structure 9110 may include first gate lines 9111 alternately stacked with first insulating layers 9112. The first gate lines 9111 may be word lines or a drain select line. The source structure 9130 may be disposed over the first gate structure 9110.

The second gate structure 9120A or 9120B may be disposed between the first gate structure 9110 and the source structure 9130. Referring to FIG. 31A, the second gate structure 9120A may include a second gate line 9121 alternately stacked with second insulating layers 9122. Referring to FIG. 31B, the second gate structure 9120B may include second gate lines 9121 alternately stacked with second insulating layers 9122. The second gate line 9121 may be a source select line. The second gate line 9121 may be thicker than the first gate line 9111 or have substantially the same thickness as the first gate line 9111. The second gate line 9121 may include a different material from the first gate line 9111. For example, the first gate line 9111 may include metal such as tungsten (W) or molybdenum (Mo), and the second gate line 9121 may include polysilicon. Consecutive second gate lines 9121 disposed at the same level may be insulated by an isolation insulating structure 9160. In a plan view, the isolation insulating structures 9160 may extend in a line or a wave or zigzag shape.

The channel structures 9140 may extend through the first gate structure 9110 and the second gate structure 9120A or 9120B. The channel structure 9140 may include a channel layer 9141, a memory layer 9142, and/or an insulating core 9143.

The first gate structure 9110 and the second gate structure 9120A or 9120B may be formed by separate processes. For example, the second gate structure 9120A or 9120B may be formed on a substrate. At least one conductive layer and the second insulating layers 9122 may be formed, and the second gate lines 9121 and trenches between the second gate lines 9121 may be formed by etching at least one conductive layer and the second insulating layers 9122. The isolation insulating structures 9160 may be formed in the trenches. The first gate structure 9110 may be formed by forming a stack including sacrificial layers alternately stacked with the first insulating layers 9112 and replacing the sacrificial layers with the first gate lines 9111. A wafer bonding process may be performed, the substrate may be removed, and the source structure 9130 may be formed. In another example, the second gate structure 9120A or 9120B including at least one conductive layer and the second insulating layers 9122 may be formed on a substrate. The first gate structure 9110 may be formed by forming a stack including sacrificial layers alternately stacked with the first insulating layers 9112 and replacing the sacrificial layers with the first gate lines 9111. A wafer bonding process may be performed, and a rear surface of the second gate structure 9120A or 9120B may be exposed by removing the substrate. The second gate lines 9121 and trenches between the second gate lines 9121 may be formed by etching at least one conductive layer and the second insulating layers 9122, and the isolation insulating structures 9160 may be formed in the trenches. The source structure 9130 may be formed.

What is claimed is:

1. An electronic device comprising:
a first conductive layer;
a second conductive layer connected to the first conductive layer;
a stacked structure including conductive layers and insulating layers which are alternately stacked, wherein the conductive layers include a selection gate of a selection transistor and gate electrodes of memory cells;
a channel layer extending through the stacked structure and including a contact surface connected to the second conductive layer;
a memory layer between the channel layer and the stacked structure, wherein the memory layer is not interposed between the contact surface and the second conductive layer; and
a sub-insulating layer passing through the selection gate.

2. The electronic device of claim 1, wherein the selection gate is separated into line patterns by the insulating layer.

3. The electronic device of claim 1, wherein the sub-insulating layer is disposed under the gate electrodes of the memory cells.

4. The electronic device of claim 1, wherein the sub-insulating layer is disposed over the gate electrodes of the memory cells.

5. The electronic device of claim 1, further comprising:
a memory pattern disposed between the channel layer and the second conductive layer except the contact surface.

6. An electronic device comprising:
a pair of slit insulating layers;
a stacked structure disposed between the pair of slit insulating layers and including conductive layers and insulating layers which are alternately stacked, wherein the conductive layers include a selection gate of a selection transistor and gate electrodes of memory cells;
a first conductive layer disposed under the stacked structure;
a second conductive layer connected to the first conductive layer;
a channel layer extending through the stacked structure and including a contact surface connected to the second conductive layer;
a memory layer between the channel layer and the stacked structure, wherein the memory layer is not interposed between the contact surface and the second conductive layer; and
sub-insulating layers disposed between the pair of slit insulating layers and passing through the selection gate.

7. The electronic device of claim 6, wherein the selection gate is separated into line patterns by the insulating layers.

8. The electronic device of claim 6, wherein the sub-insulating layers are disposed under the gate electrodes of the memory cells.

9. The electronic device of claim 6, wherein the sub-insulating layers are disposed over the gate electrodes of the memory cells.

10. The electronic device of claim 6, further comprising:
a memory pattern disposed between the channel layer and the second conductive layer, wherein the memory pattern is not disposed between the contact surface and the second conductive layer.

11. The electronic device of claim 6, wherein the sub-insulating layers are spaced apart from each other in a first direction and extend in a second direction intersecting the first direction.

12. The electronic device of claim 11, wherein the pair of slit insulating layers extend in the second direction.
